(19) United States
(12) Patent Application Publication
(10) Pub. No.: US 2026/0223375 A1
(43) Pub. Date: Jul. 30, 2026

(54) NON-VOLATILE MEMORY DEVICE

(71) Applicant: SAMSUNG ELECTRONICS CO., LTD., Suwon-si (KR)

(72) Inventors: Myunghun LEE, Suwon-si (KR); Hyuckjoon Kwon, Suwon-si (KR); Junhyoung KIM, Suwon-si (KR); Sangwon PARK, Suwon-si (KR); Jinho JEON, Suwon-si (KR)

(73) Assignee: SAMSUNG ELECTRONICS CO., LTD., Suwon-si (KR)

(21) Appl. No.: 19/442,541

(22) Filed: Jan. 7, 2026

(30) Foreign Application Priority Data
Jan. 24, 2025 (KR) 10-2025-0011895

(51) Int. Cl. H10B 80/00; H10W 90/00; H10W 90/20

(52) U.S. Cl. CPC H10B 80/00; H10W 90/20; H10W 90/792

(57) ABSTRACT

A non-volatile memory device may include: a memory cell region including at least one memory cell array and upper bonding pads, wherein the at least one memory cell array including: a plurality of sub-planes disposed in a first direction; and a plurality of common source plates respectively electrically connected to the plurality of sub-planes; and a peripheral circuit region including: lower bonding pads, the peripheral circuit region being electrically connected to the memory cell region in a vertical direction by the upper bonding pads and the lower bonding pads; and a plurality of common source line drivers respectively electrically connected to the plurality of common source plates, and configured to independently drive the plurality of common source plates.

### CROSS-REFERENCE TO RELATED APPLICATION

This application is based on and claims priority under 35 U.S.C. § 119 to Korean Patent Application No. 10-2025-0011895, filed on Jan. 24, 2025, in the Korean Intellectual Property Office, the disclosure of which is incorporated by reference herein in its entirety.

### BACKGROUND

### 1. Field

The disclosure relates to a memory device. More specifically, the disclosure relates to a three-dimensional (3D) non-volatile memory device where a memory cell array is disposed in a vertical direction with respect to a peripheral circuit.

### 2. Description of Related Art

As high-capacity and miniaturized non-volatile memory devices are needed, 3D non-volatile memory devices where a memory cell array and a peripheral circuit are arranged in a vertical direction have been developed. As semiconductor process technology advances, it is continuously required to decrease the size of a chip where a 3D non-volatile memory device is implemented. Also, the demand for reducing the power consumption of 3D non-volatile memory devices is increasing.

### SUMMARY

The disclosure provides a non-volatile memory device which enables a chip size and power consumption to be reduced.

According to an aspect of the disclosure, a non-volatile memory device may include: a memory cell region including at least one memory cell array and upper bonding pads, wherein the at least one memory cell array including: a plurality of sub-planes disposed in a first direction; and a plurality of common source plates respectively electrically connected to the plurality of sub-planes; and a peripheral circuit region including: lower bonding pads, the peripheral circuit region being electrically connected to the memory cell region in a vertical direction by the upper bonding pads and the lower bonding pads; and a plurality of common source line drivers respectively electrically connected to the plurality of common source plates, and configured to independently drive the plurality of common source plates.

According to an aspect of the disclosure, a non-volatile memory device may include: a memory cell region including: at least one memory cell array including: a first sub-plane; a second sub-plane adjacent to the first sub-plane in a first direction; a third sub-plane adjacent to the first sub-plane in a second direction intersecting the first direction; a fourth sub-plane adjacent to the third sub-plane in the first direction and adjacent to the second sub-plane in the second direction; and a plurality of common source plates electrically connected to the first sub-plane, the second sub-plane, the third sub-plane, and the fourth sub-plane; and upper bonding pads; and a peripheral circuit region including: lower bonding pads, the peripheral circuit region being electrically connected to the memory cell region in a vertical direction by the upper bonding pads and the lower bonding pads; and a plurality of common source line drivers respectively electrically connected to the plurality of common source plates, wherein the plurality of common source line drivers are configured to independently drive the plurality of common source plates.

According to an aspect of the disclosure, a non-volatile memory device may include: a memory cell region including: at least one memory cell array including: a first sub-plane and a second sub-plane arranged in a second direction; a first common source plate electrically connected to the first sub-plane; and a second common source plate electrically connected to the second sub-plane; and upper bonding pads; and a peripheral circuit region including: lower bonding pads, the peripheral circuit region being electrically connected to the memory cell region in a vertical direction by the upper bonding pads and the lower bonding pads; a first common source line driver electrically connected to the first common source plate; and a second common source line driver electrically connected to the second common source plate. The first common source line driver and the second common source line driver may be configured to independently drive the first common source plate and the second common source plate.

### BRIEF DESCRIPTION OF THE DRAWINGS

Embodiments will be more clearly understood from the following detailed description taken in conjunction with the accompanying drawings in which:

FIG. 1 is a block diagram illustrating a memory device according to one or more embodiments;

FIG. 2 is a circuit diagram illustrating a memory block according to one or more embodiments;

FIG. 3 schematically illustrates a structure of a memory device according to one or more embodiments;

FIG. 4 schematically illustrates a memory device having a B-VNAND structure, according to one or more embodiments;

FIG. 5A illustrates memory devices according to one or more embodiments;

FIG. 5B illustrates memory devices according to one or more embodiments;

FIG. 6A illustrates a memory device according to and one or more embodiments;

FIG. 6B illustrates a read operation timing diagram of the memory device of FIG. 6A according to one or more embodiments;

FIG. 7A illustrates a connection between sub-planes and common source line drivers according to and one or more embodiments;

FIG. 7B illustrates a connection between sub-planes and common source line drivers according to one or more embodiments;

FIG. 8 is a plan view illustrating a memory device according to one or more embodiments;

FIG. 9A is a plan view illustrating a memory device according to one or more embodiments;

FIG. 9B is a plan view illustrating a memory device according to one or more embodiments;

FIG. 9C is a plan view illustrating a memory device according to one or more embodiments;

FIG. 10 illustrates a cross-sectional view taken along line Y1-Y2 of FIG. 9B, according to one or more embodiments;

FIG. 11 illustrates a cross-sectional view taken along line X1-X2 of FIG. 9B, according to one or more embodiments;

FIG. 12 schematically illustrates a memory device having a B-VNAND structure, according to one or more embodiments;

FIG. 13 schematically illustrates a memory device having a B-VNAND structure, according to one or more embodiments;

FIG. 14A is a plan view illustrating a memory device according to one or more embodiments;

FIG. 14B is a plan view illustrating a memory device according to one or more embodiments;

FIG. 15A is a plan view illustrating a memory device according to one or more embodiments;

FIG. 15B is a plan view illustrating a memory device according to one or more embodiments;

FIG. 16A is a plan view illustrating a memory device according to one or more embodiments;

FIG. 16B is a plan view illustrating a memory device according to one or more embodiments;

FIG. 16C is a plan view illustrating a memory device according to one or more embodiments;

FIG. 17A is a plan view illustrating a memory device according to one or more embodiments;

FIG. 17B is a plan view illustrating a memory device according to one or more embodiments;

FIG. 17C is a plan view illustrating a memory device according to one or more embodiments;

FIG. 18A is a plan view illustrating a memory device according to one or more embodiments;

FIG. 18B is a plan view illustrating a memory device according to one or more embodiments;

FIG. 19 is a plan view illustrating a memory device according to one or more embodiments;

FIG. 20 is a cross-sectional view of a memory device having a B-VNAND structure, according to one or more embodiments; and

FIG. 21 illustrates a solid state drive (SSD) including a memory device according to one or more embodiments.

### DETAILED DESCRIPTION

Hereinafter, embodiments will be described in detail with reference to the accompanying drawings.

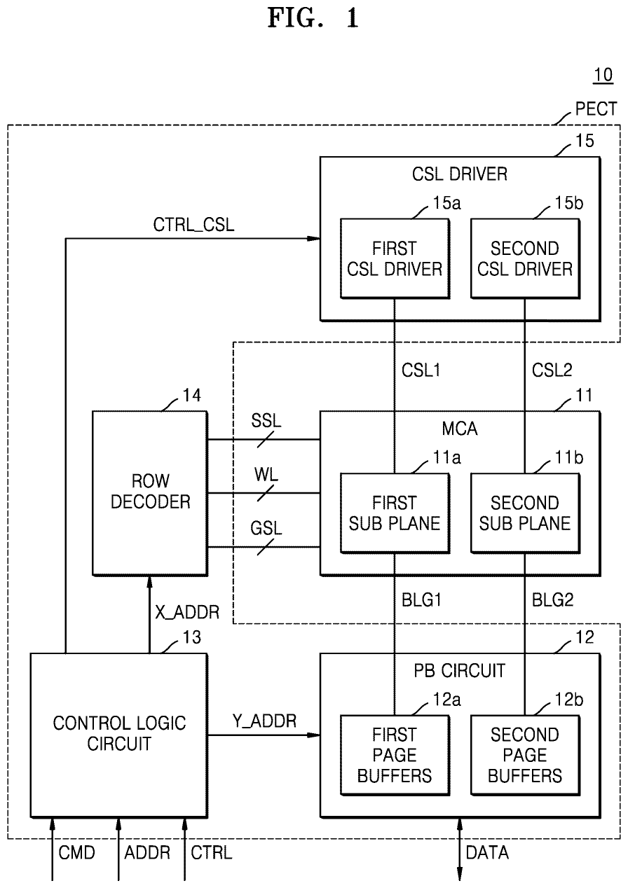

FIG. 1 is a block diagram illustrating a memory device 10 according to one or more embodiments.

Referring to FIG. 1, the memory device 10 may include a memory cell array 11 and a peripheral circuit PECT, and the peripheral circuit PECT may include a page buffer circuit 12, a control logic circuit 13, a row decoder 14, and a common source line driver 15. According to one or more embodiments, the peripheral circuit PECT may further include a data input/output (I/O) circuit or an I/O interface. Also, according to one or more embodiments, the peripheral circuit PECT may further include a temperature sensor, a command decoder, and an address decoder. Herein, the memory device 10 may be referred to as a “non-volatile memory device”.

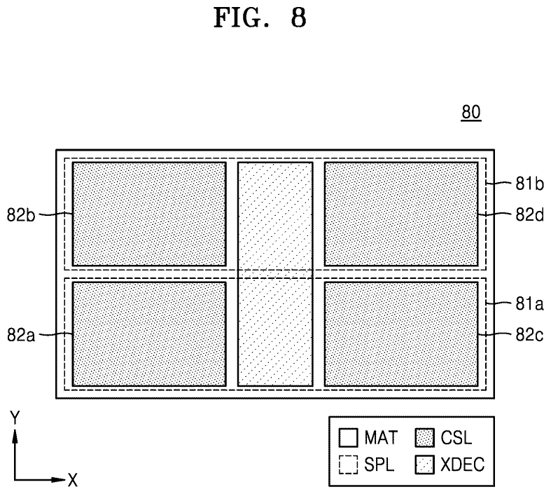

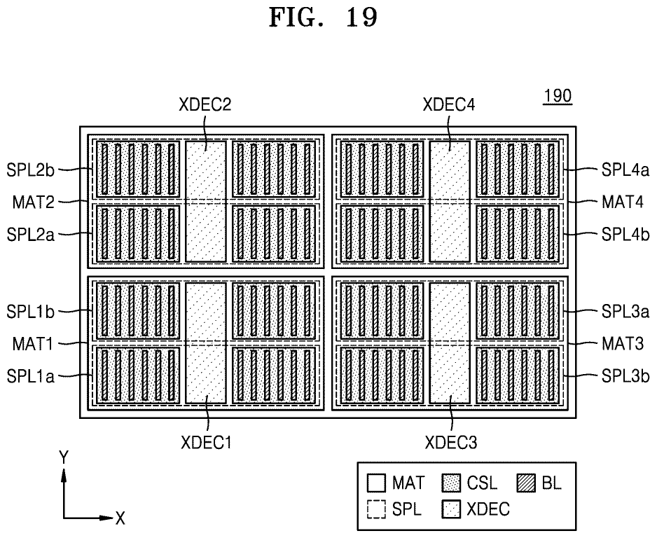

The memory cell array 11 may include a plurality of sub-planes including a first sub-plane 11a and a second sub-plane 11b. For example, the memory cell array 11 may correspond to a memory cell array tile (MAT). For example, the memory cell array 11 may correspond to an MAT of FIGS. 8 to 9C and 14A to 18B or one of first to fourth MATs MAT1 to MAT4 of FIG. 19. For example, the memory cell array 11 may have a capacity of about 16 KB, but the disclosure is not limited thereto. According to one or more embodiments, the memory cell array 11 may be referred to as a memory plane or a plane.

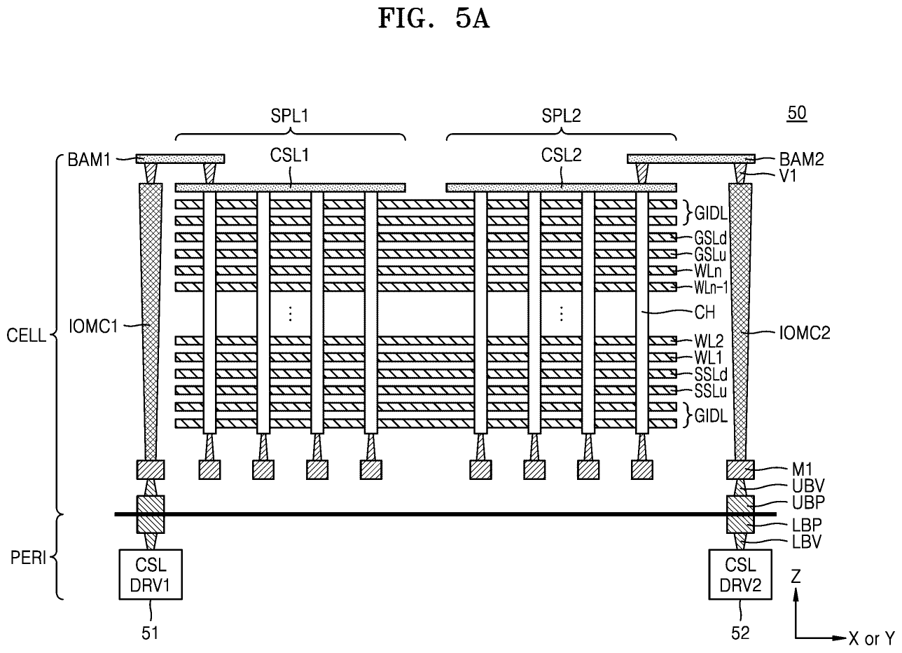

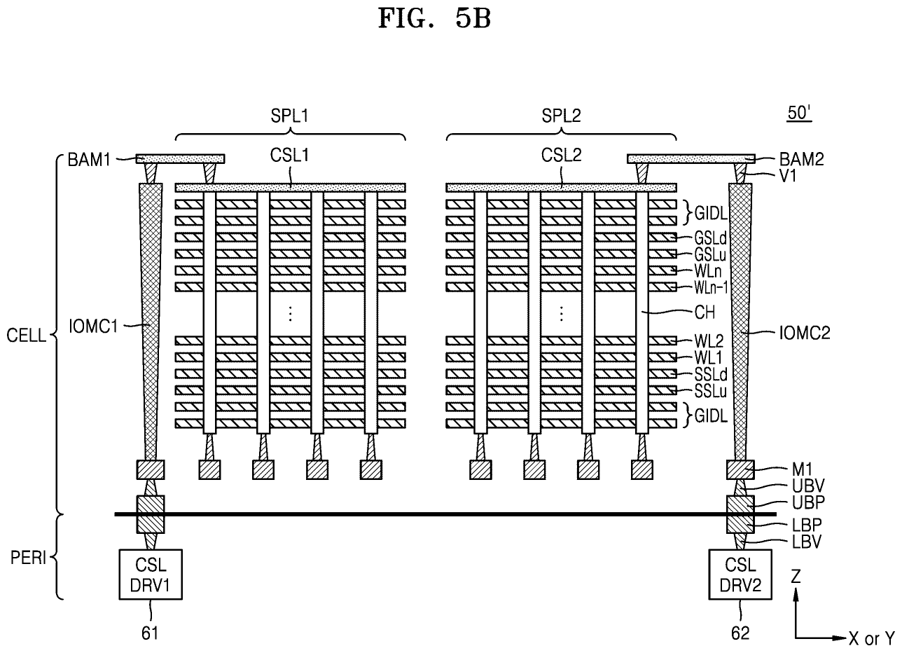

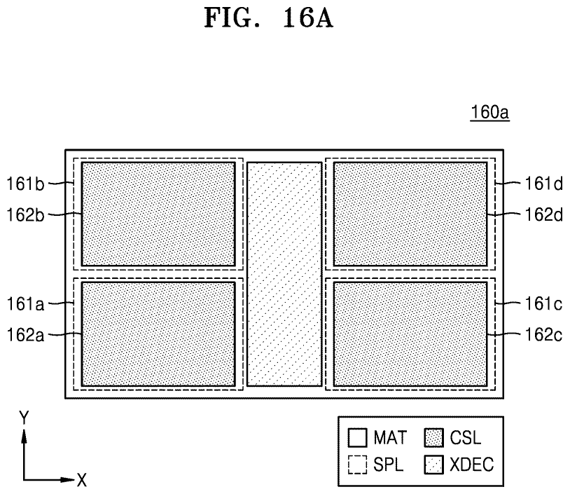

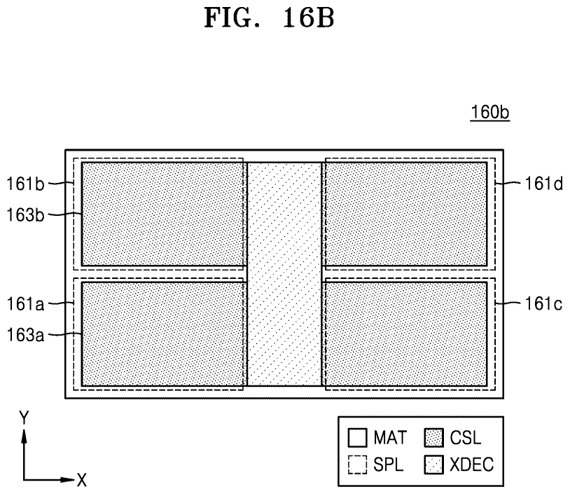

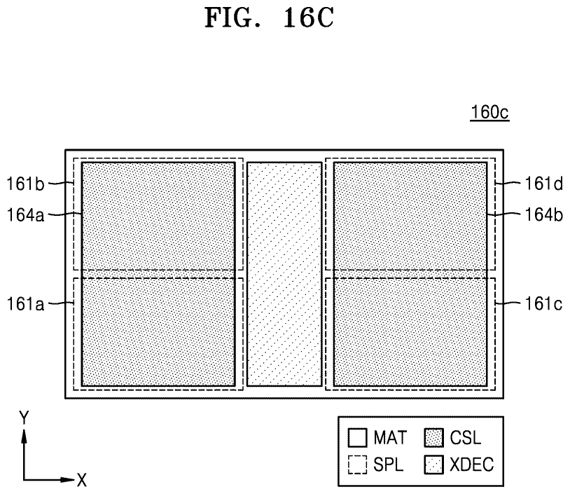

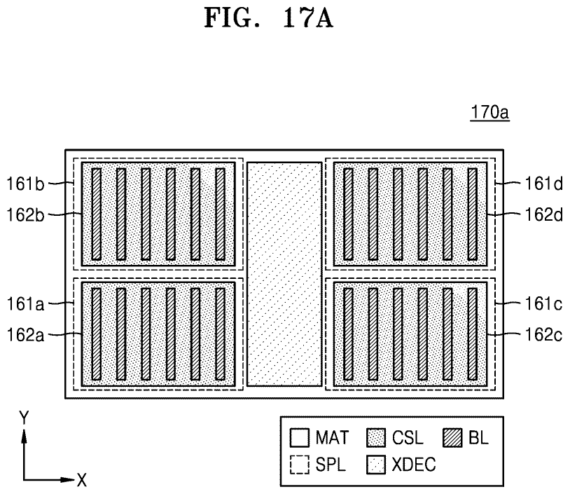

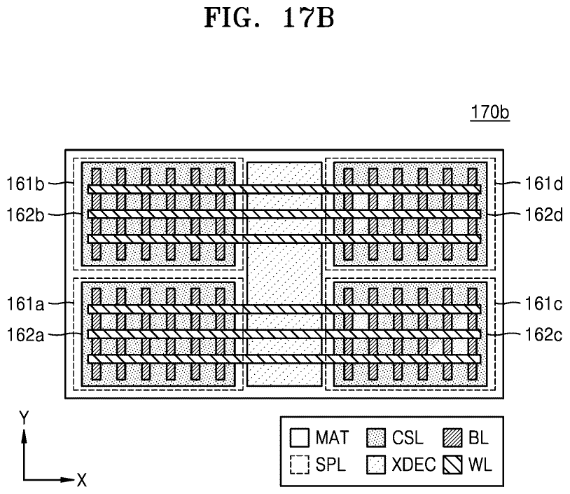

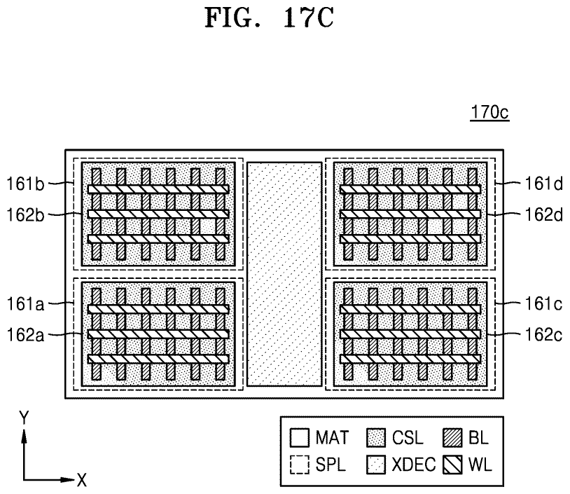

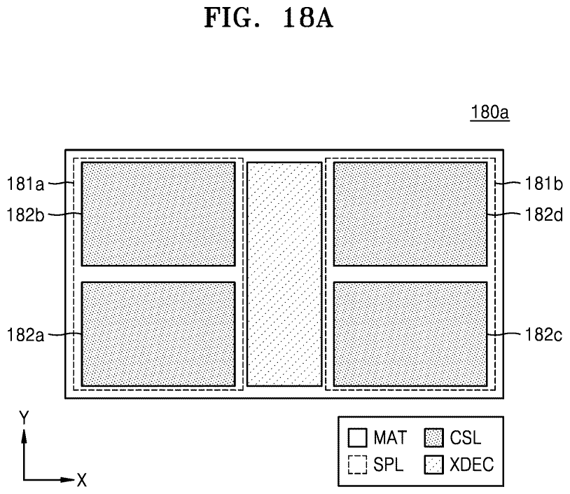

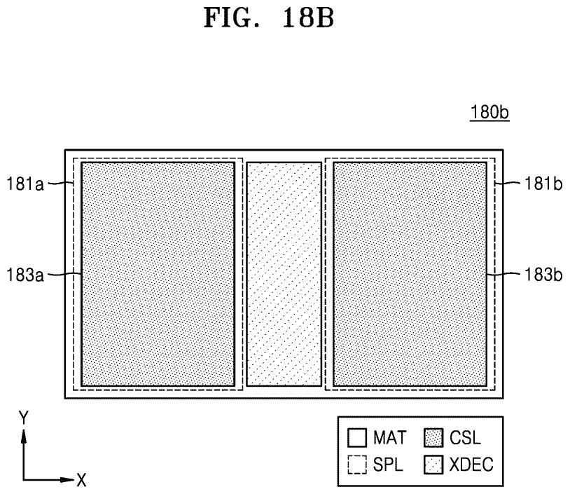

In one or more embodiments, the first and second sub-planes 11a and 11b may be arranged in a first direction (for example, Y of FIG. 5A) and may respectively extend in a second direction (for example, X of FIG. 5A) intersecting the first direction. This will be described below with reference to FIGS. 8 to 15B. Herein, the first direction may correspond to an extension direction of bit lines. In one or more embodiments, the first and second sub-planes 11a and 11b may be arranged in the second direction X and may respectively extend in the first direction Y. This will be described below with reference to FIGS. 18A and 18B. In one or more embodiments, the plurality of sub-planes including the first and second sub-planes 11a and 11b may be arranged in an array form. This will be described below with reference to FIGS. 16A to 17C. For example, the plurality of sub-planes may include four sub-planes arranged as a 2×2 array. For example, the plurality of sub-planes may include nine sub-planes arranged as a 3×3 array.

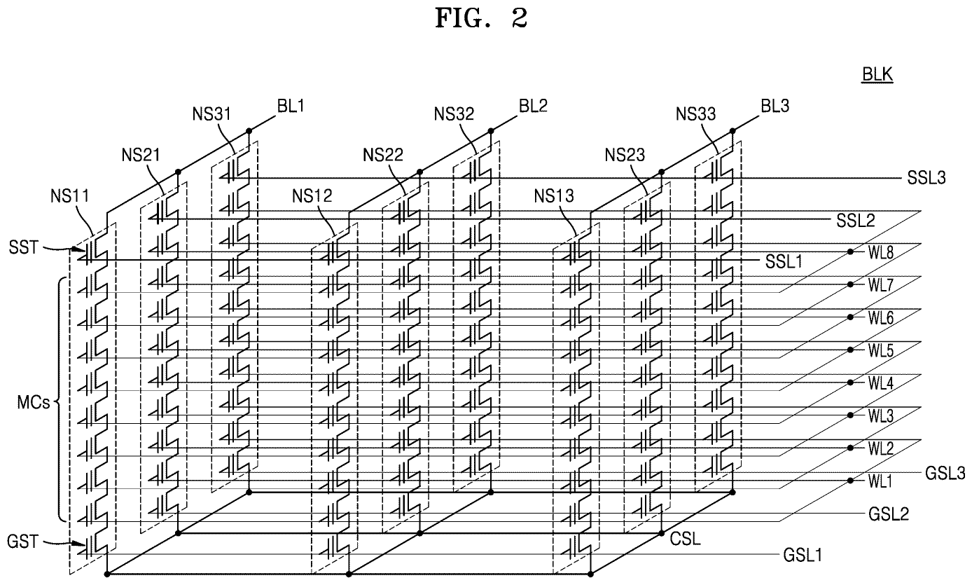

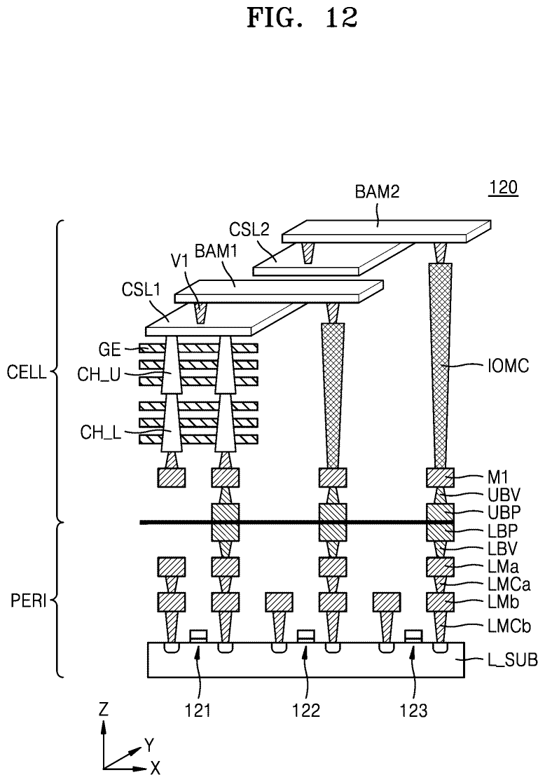

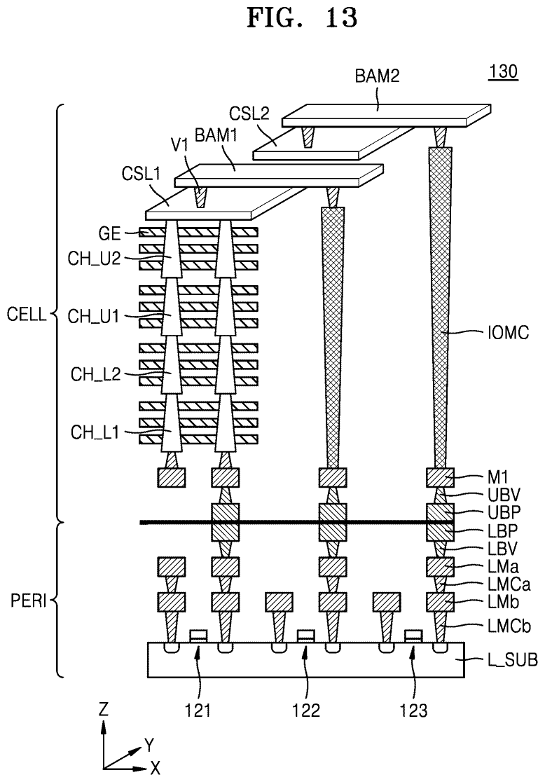

For example, each of the first and second sub-planes 11a and 11b may have a capacity of about 8 KB, but the disclosure is not limited thereto. For example, each of the first and second sub-planes 11a and 11b may include a plurality of memory blocks, and each of the memory blocks may include a plurality of memory cells. This will be described below in detail with reference to FIG. 2. For example, each memory block may include a plurality of memory stacks. This will be described below in detail with reference to FIGS. 12 and 13.

In one or more embodiments, the first sub-plane 11a may be connected to a first plate common source line CSL or a first common source plate CSL1, and the second sub-plane 11b may be connected to a second plate CSL or a second common source plate CSL2. Herein, the term “connected” may mean electrically connected. As described above, the first and second sub-planes 11a and 11b may be respectively connected to the first and second common source plates CSL1 and CSL2, and thus, may be independently controlled.

Herein, a “common source plate” may be referred to as a CSL structure which has a plate shape and is connected to a plurality of memory blocks in common. For example, the first and second common source plates CSL1 and CSL2 may each extend in the first direction Y and may be apart from each other in the second direction X. For example, the first and second common source plates CSL1 and CSL2 may each extend in the second direction X and may be apart from each other in the first direction Y.

In one or more embodiments, the first sub-plane 11a may be connected to a first bit line group BLG1 including first bit lines each extending in the first direction Y, and the second sub-plane 11b may be connected to a second bit line group BLG2 including second bit lines each extending in the first direction Y. As described above, the first and second sub-planes 11a and 11b may be respectively connected to the first and second bit line groups BLG1 and BLG2, and thus, may be independently controlled.

The memory cell array 11 may be connected to the row decoder 14 through word lines WL, string selection lines SSL, and ground selection lines GSL. For example, memory cells included in the memory cell array 11 may be flash memory cells. Hereinafter, a case where memory cells are NAND flash memory cells will be described as an example of embodiments. However, the disclosure is not limited thereto, and in one or more embodiments, memory cells may be resistive memory cells such as resistive random access memory (RAM) (ReRAM), phase change RAM (PRAM), or magnetic RAM (MRAM).

In one or more embodiments, the memory cell array 11 may include a three-dimensional (3D) memory cell array, the 3D memory cell array may include a plurality of NAND strings, and each of the NAND strings may include memory cells which are respectively connected to word lines vertically stacked on a substrate. This will be described below in detail with reference to FIG. 2. U.S. Pat. Publication Nos. 7,679,133, 8,553,466, 8,654,587 and 8,559,235 and U.S. Patent Application No. 2011/0233648 disclose appropriate elements of a 3D memory array which includes a plurality of levels and in which word lines and/or bit lines are shared between the plurality of levels. In the present specification, the reference documents may be incorporated herein by reference.

The page buffer circuit 12 may include a plurality of page buffers which include first page buffers 12a and second page buffers 12b. The first page buffers 12a may be connected to memory cells of the first sub-plane 11a through the first bit line group BLG1, and the second page buffers 12b may be connected to memory cells of the second sub-plane 11b through the second bit line group BLG2. The page buffer circuit 12 may select at least one bit line from among the first and second bit line groups BLG1 and BLG2 based on control by the control logic circuit 13. For example, the page buffer circuit 12 may select some bit lines in response to a column address Y_ADDR received from the control logic circuit 13.

Each of the first and second page buffers 12a and 12b may operate as a write driver or a sense amplifier. For example, in a program operation, each of the first and second page buffers 12a and 12b may apply a voltage, corresponding to data DATA to be programmed, to a bit line to store the data DATA in a memory cell. For example, in a program verify operation or a read operation, each of the first and second page buffers 12a and 12b may sense a current or a voltage through a bit line to sense programmed data DATA.

The control logic circuit 13 may output various control signals (for example, a row address X_ADDR, a column address Y_ADDR, and a control signal CTRL_CSL) for programming data in the memory cell array 11, reading data from the memory cell array 11, or erasing data stored in the memory cell array 11, based on a command CMD, an address ADDR, and a control signal CTRL. Therefore, the control logic circuit 13 may overall control various operations of the memory device 10. For example, the control logic circuit 13 may receive the command CMD, the address ADDR, and the control signal CTRL from a memory controller.

In response to the row address X_ADDR received from the control logic circuit 13, the row decoder 14 may select one memory block from among a plurality of memory blocks included in the first and second sub-planes 11a and 11b, select one word line WL from among word lines WL of the selected memory block, and select one string selection line SSL from among string selection lines SSL. For example, in a program operation, the row decoder 14 may apply a program voltage and a program verify voltage to the selected word line WL, and in a read operation, the row decoder 14 may apply a read voltage to the selected word line WL.

The CSL driver 15 may include a plurality of CSL drivers which include a first CSL driver 15a and a second CSL driver 15b. The first CSL driver 15a may be connected to the memory cells of the first sub-plane 11a through the first common source plate CSL1, and the second CSL driver 15b may be connected to the memory cells of the second sub-plane 11b through the second common source plate CSL2. The first and second CSL drivers 15a and 15b may selectively operate based on control by the control logic circuit 13.

For example, the first and second CSL drivers 15a and 15b may be enabled or disabled in response to the control signal CTRL_CSL received from the control logic circuit 13. For example, when the first CSL driver 15a is enabled, the first CSL driver 15a may provide a bias voltage to the first common source plate CSL1. For example, when the first CSL driver 15a is disabled, the first common source plate CSL1 may be floated. As described above, only a CSL driver connected to a sub-plane which is operating may be enabled, and thus, the power consumption of the memory device 10 may decrease.

For example, when performing an operation on the first sub-plane 11a, the first CSL driver 15a may be enabled, and the second CSL driver 15b may be disabled. For example, when performing an operation on the first sub-plane 11a, the first CSL driver 15a may apply a bias voltage to the first common source plate CSL1, and the second CSL driver 15b may be disabled, and thus, the second common source plate CSL2 may be floated. For example, when performing an operation on the second sub-plane 11b, the first CSL driver 15a may be disabled, and the second CSL driver 15b may be enabled. For example, when performing an operation on the second sub-plane 11b, the first CSL driver 15a may be disabled, the first common source plate CSL1 may be floated, and the second CSL driver 15b may apply a bias voltage to the second common source plate CSL2.

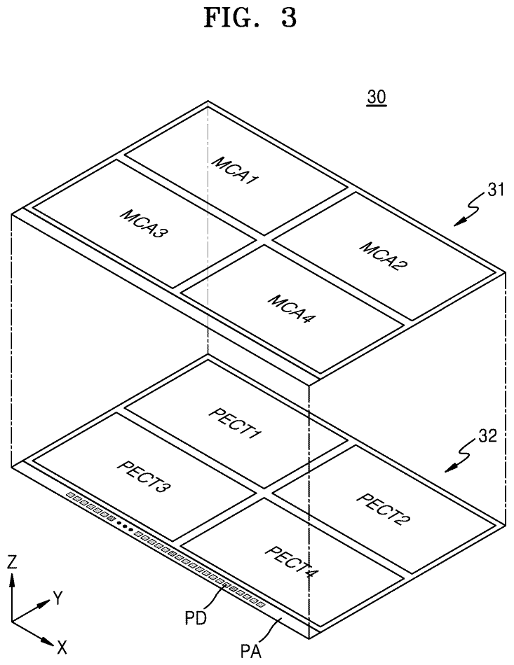

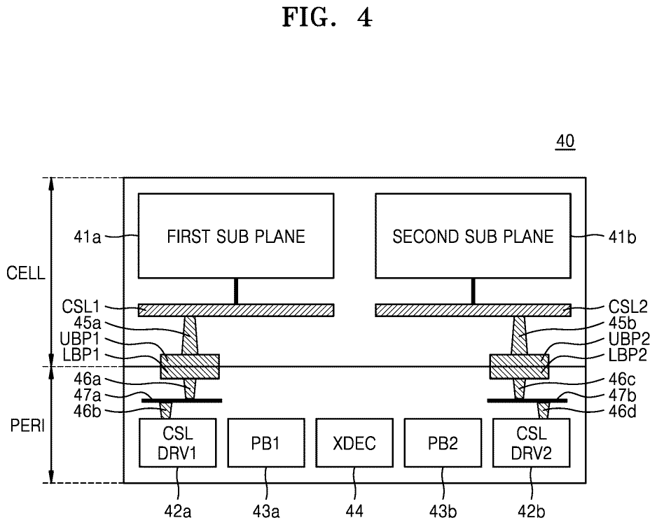

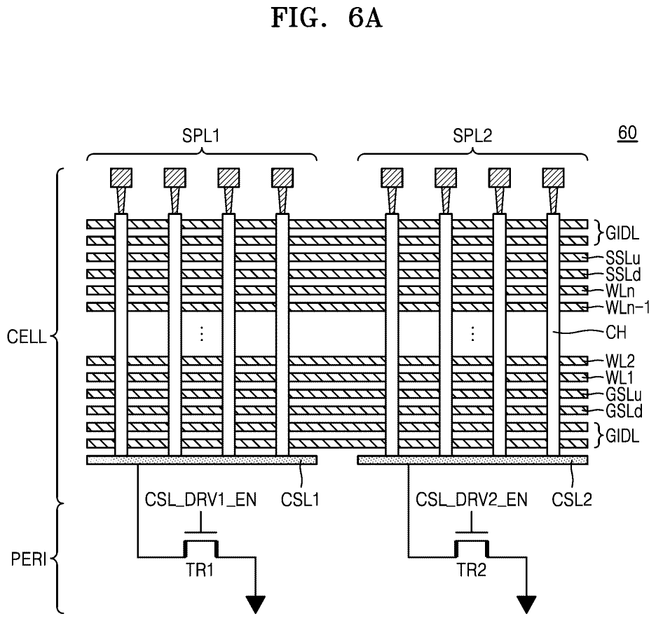

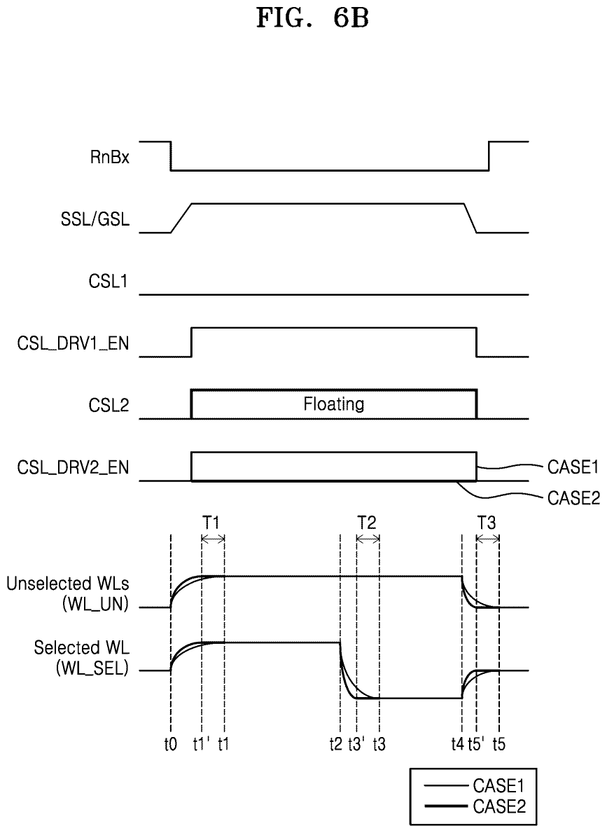

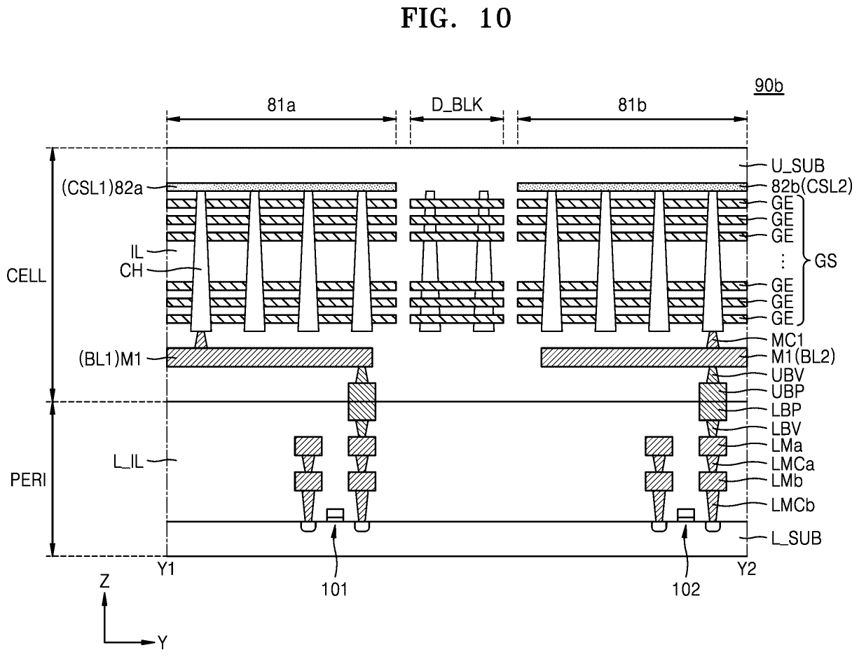

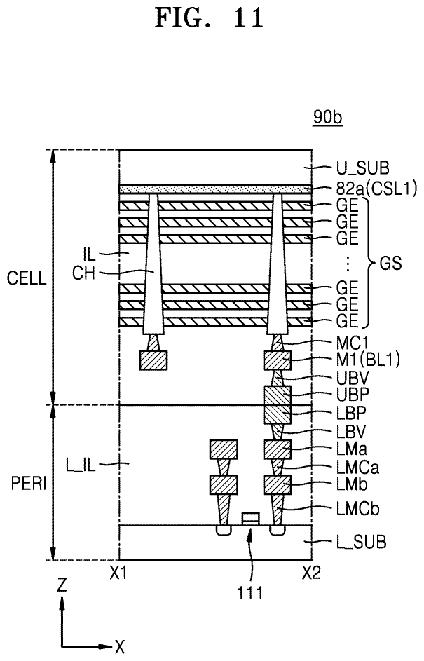

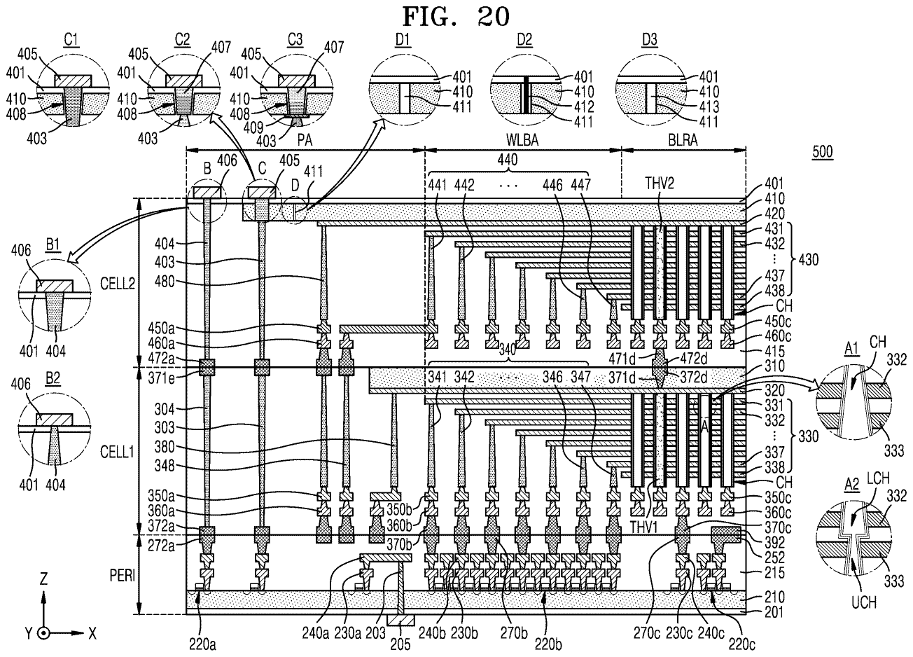

According to one or more embodiments, the memory cell array 11 may be disposed in a memory cell region, a first semiconductor layer, a first wafer, a first semiconductor chip, or a memory chip (for example, 31 of FIG. 3, CELL of FIG. 4, CELL of FIGS. 5A and 5B, CELL of FIG. 6A, CELL of FIG. 10, CELL of FIG. 11, CELL of FIG. 12, CELL of FIG. 13, or CELL1 and CELL2 of FIG. 20), and the peripheral circuit PECT may be disposed in a peripheral circuit region, a second semiconductor layer, a second wafer, a second semiconductor chip, or a peripheral circuit chip (for example, 32 of FIG. 3, PERI of FIGS. 5A and 5B, PERI of FIG. 6A, PERI of FIG. 10, PERI of FIG. 11, PERI of FIG. 12, PERI of FIG. 13, or PERI of FIG. 20). Accordingly, at least a portion of the peripheral circuit PECT may overlap the memory cell array 11 in a vertical direction.

FIG. 2 is a circuit diagram illustrating a memory block BLK according to one or more embodiments.

Referring to FIG. 2, the memory block BLK may correspond to one of a plurality of memory blocks included in the first and second sub-planes 11a and 11b of FIG. 1. The memory block BLK may include NAND strings NS11 to NS33, and each (for example, NS11) of the NAND strings NS11 to NS33 may include a string selection transistor SST, a plurality of memory cells MCs, and a ground selection transistor GST, which are serially connected to one another. The transistors SST and GST and the memory cells MCs included in each NAND string may configure a structure which is stacked in a vertical direction on a substrate.

Bit lines (for example, first to third bit lines) BL1 to BL3 may extend in a first direction (for example, a Y direction of FIG. 3), and word lines WL1 to WL8 may extend in a second direction (for example, an X direction of FIG. 3). According to one or more embodiments, the first direction may be referred to as a first horizontal direction, and the second direction may be referred to as a second horizontal direction. NAND strings NS11, NS21, and NS31 may be disposed between the first bit line BL1 and a common source line CSL, NAND strings NS12, NS22, and NS32 may be disposed between the second bit line BL2 and the common source line CSL, and NAND strings NS13, NS23, and NS33 may be disposed between the third bit line BL3 and the common source line CSL. For example, the common source line CSL may correspond to the first common source plate CSL1 or the second common source plate CSL2 of FIG. 1. For example, the bit lines BL1 to BL3 may be included in the first bit line group BLG1 or the second bit line group BLG2 of FIG. 1.

The string selection transistor SST may be connected to corresponding string selection lines SSL1 to SSL3. The memory cells MCs may be respectively connected to corresponding word lines WL1 to WL8. The ground selection transistor GST may be connected to corresponding ground selection lines GSL1 to GSL3. The string selection transistor SST may be connected to a corresponding bit line, and the ground selection transistor GST may be connected to the common source line CSL. Here, the number of NAND strings, the number of word lines, the number of bit lines, the number of ground selection lines, and the number of string selection lines may be variously changed according to embodiments.

FIG. 3 schematically illustrates a structure of a memory device 30 according to one or more embodiments;

Referring to FIG. 3, the memory device 30 may include a memory cell region 31 and a peripheral circuit region 32 and may correspond to an implementation example of the memory device 10 of FIG. 1. The memory cell region 31 may be formed in a first wafer, and thus, may be referred to as a memory chip or a first semiconductor chip. The peripheral circuit region 32 may be formed in a second wafer, and thus, may be referred to as a peripheral circuit chip or a second semiconductor chip. In one or more embodiments, the memory cell region 31 and the peripheral circuit region 32 may be connected to each other in a vertical direction Z by a bonding manner, and thus, the memory device 30 may be referred to as a memory device of a bonding vertical NAND (B-VNAND) type or a chip-to-chip (C2C) bonding structure.

In one or more embodiments, the memory cell region 31 may include first to fourth memory cell arrays MCA1 to MCA4. For example, one of the first to fourth memory cell arrays MCA1 to MCA4 may correspond to the memory cell array 110 of FIG. 1. In this case, each of the first to fourth memory cell arrays MCA1 to MCA4 may be referred to as a memory plane or an MAT, and thus, the memory cell region 31 may have a 4-MAT structure. The peripheral circuit region 32 may include first to fourth peripheral circuits PECT1 to PECT4 respectively corresponding to the first to fourth memory cell arrays MCA1 to MCA4. Also, the peripheral circuit region 32 may further include a pad region PA where a plurality of pads PD are disposed.

In one or more embodiments, each of the first to fourth memory cell arrays MCA1 to MCA4 may include a plurality of sub-planes which are arranged in a first direction Y and/or a second direction X. In one or more embodiments, each of the first to fourth memory cell arrays MCA1 to MCA4 may include a plurality of common source plates respectively connected to the plurality sub-planes and a plurality of bit line groups respectively connected to the plurality sub-planes. The peripheral circuit region 32 may include a plurality of page buffers respectively connected to the plurality of bit line groups.

In one or more embodiments, each sub-plane may further include a word line which is connected to a plurality of sub-planes in common (e.g. connected to all of the sub-planes simultaneously). This will be described below in detail with reference to FIG. 5A. In one or more embodiments, each sub-plane may further include a plurality of word lines which are respectively connected to a plurality of sub-planes. This will be described below in detail with reference to FIG. 5B. In one or more embodiments, each sub-plane may include a plurality of memory blocks and a plurality of word line groups. For example, the plurality of memory blocks may include first to fourth memory blocks, and the plurality of word line groups may include a first word line group connected to the first and second memory blocks in common and a second word line group connected to the third and fourth memory blocks in common. For example, the plurality of memory blocks may include first to fourth memory blocks, and the plurality of word line groups may include a first word line group connected to the first memory block, a second word line group connected to the second memory block, a third word line group connected to the third memory block, and a fourth word line group connected to the fourth memory block.

FIG. 4 schematically illustrates a memory device 40 having a B-VNAND structure, according to one or more embodiments.

Referring to FIG. 4, the memory device 40 may include a memory cell region CELL and a peripheral circuit region PERI. The memory cell region CELL may include first and second sub-planes 41a and 41b and upper bonding pads UBP1 and UBP2. In the memory cell region CELL, the upper bonding pad UBP1 may be connected to a first common source plate CSL1 through a via 45a, and the first common source plate CSL1 may be connected to the first sub-plane 41a. In the memory cell region CELL, the upper bonding pad UBP2 may be connected to a second common source plate CSL2 through a via 45b, and the second common source plate CSL2 may be connected to the second sub-plane 41b. For example, the first and second sub-planes 41a and 41b may respectively correspond to the first and second sub-planes 11a and 11b of FIG. 1.

The peripheral circuit region PERI may include a first CSL driver (CSL DRV1) 42a, a second CSL driver (CSL DRV2) 42b, a first page buffer (PB1) 43a, a second page buffer (PB2) 43b, a row decoder 44, and lower bonding pads LBP1 and LBP2. In the peripheral circuit region PERI, the lower bonding pad LBP1 may be connected to the first CSL driver 42a, and the lower bonding pad LBP2 may be connected to the second CSL driver 42b. For example, the lower bonding pad LBP1 may be connected to the first CSL driver 42a through vias 46a and 46b and a lower metal layer 47a. For example, the lower bonding pad LBP2 may be connected to the second CSL driver 42b through vias 46c and 46d and a lower metal layer 47b.

For example, the first CSL driver 42a may correspond to the first CSL driver 15a of FIG. 1, and the second CSL driver 42b may correspond to the second CSL driver 15b of FIG. 1. For example, the first page buffer 43a may correspond to one of the first page buffers 12a of FIG. 1, and the second page buffer 43b may correspond to one of the second page buffers 12b of FIG. 1.

FIG. 5A illustrates a memory device 50 according to one or more embodiments.

Referring to FIG. 5A, the memory device 50 may include a memory cell region CELL and a peripheral circuit region PERI. The memory cell region CELL may include a first sub-plane SPL1 and a second sub-plane SPL2. Each of the first and second sub-planes SPL1 and SPL2 may include channel structures CH which extend in a vertical direction Z. In one or more embodiments, the first and second sub-planes SPL1 and SPL2 may be arranged in a first direction Y. In one or more embodiments, the first and second sub-planes SPL1 and SPL2 may be arranged in a second direction X. However, the disclosure is not limited thereto, and in one or more embodiments, the first and second sub-planes SPL1 and SPL2 may be arranged in a diagonal direction.

The memory cell region CELL may include word lines WL1 to WLn (where n may be a positive integer), string selection lines SSLd and SSLu, ground selection lines GSLd and GSLu, and gate induced drain leakage (GIDL) control lines GIDL, which are stacked in the vertical direction Z. According to one or more embodiments, the word lines WL1 to WLn, the string selection lines SSLd and SSLu, the ground selection lines GSLd and GSLu, and the GIDL control lines GIDL may be referred to as gate lines (for example, GE of FIG. 10) and may configure a gate structure (for example, GS of FIG. 10).

According to one or more embodiments, the word lines WL1 to WLn may be shared by the first and second sub-planes SPL1 and SPL2, and the first and second common source plates CSL1 and CSL2 may be respectively connected to the first and second sub-planes SPL1 and SPL2. As described above, the first and second sub-planes SPL1 and SPL2 may be connected to different common source plates despite being connected to the same word line, and thus, the first and second sub-planes SPL1 and SPL2 may be individually controlled.

In one or more embodiments, the word lines WL1 to WLn, the string selection lines SSLd and SSLu, the ground selection lines GSLd and GSLu, and the GIDL control lines GIDL may be shared by the first and second sub-planes SPL1 and SPL2. For example, the word line WL1 may be connected to the first and second sub-planes SPL1 and SPL2 in common. For example, the string selection lines SSLd and SSLu may be connected to the first and second sub-planes SPL1 and SPL2 in common. For example, the ground selection lines GSLd and GSLu may be connected to the first and second sub-planes SPL1 and SPL2 in common.

The memory cell CELL may further include first and second input output metal contacts or first and second input output contact plugs IOMC1 and IOMC2, first and second upper metal patterns BAM1 and BAM2, vias V1, a first metal layer M1, an upper bonding via UBV, and an upper bonding pad UBP. The peripheral circuit region PERI may include first and second CSL drivers 51 and 52, the upper bonding via UBV, and the upper bonding pad UBP. The first common source plate CSL1 may be connected to the first CSL driver 51, and the second common source plate CSL2 may be connected to the second CSL driver 52.

For example, the first common source plate CSL1 may be connected to the first common source driver 51 through the via V1, the first upper metal pattern BAM1, the first input output contact plug IOMC1, the first metal layer M1, the upper bonding via UBV, the upper bonding pad UBP, the lower bonding pad LBP, and the lower bonding via LBV. For example, the second common source plate CSL2 may be connected to the second common source driver 52 through the via V1, the second upper metal pattern BAM2, the second input output contact plug IOMC2, the first metal layer M1, the upper bonding via UBV, the upper bonding pad UBP, the lower bonding pad LBP, and the lower bonding via LBV.

FIG. 5B illustrates a memory device 50′ according to one or more embodiments.

Referring to FIG. 5B, the memory device 50′ may correspond to a modification example of FIG. 5A, and the description of FIG. 5A may be applied to the embodiment of FIG. 5B. Hereinafter, the difference between the memory device 50′ and the memory device 50 of FIG. 5A will be mainly described. A first common source plate CSL1 may be connected to a first CSL driver 51, and a second common source plate CSL2 may be connected to a second CSL driver 52.

According to one or more embodiments, word lines WL1 to WLn may not be shared by first and second sub-planes SPL1 and SPL2, and first and second common source plates CSL1 and CSL2 may be respectively connected to the first and second sub-planes SPL1 and SPL2. As described above, the first and second sub-planes SPL1 and SPL2 may be respectively connected to different word lines and may be respectively connected to different common source plates, and thus, the first and second sub-planes SPL1 and SPL2 may be individually controlled.

In one or more embodiments, the word lines WL1 to WLn, the string selection lines SSLd and SSLu, the ground selection lines GSLd and GSLu, and the GIDL control lines GIDL may not be shared by the first and second sub-planes SPL1 and SPL2. For example, a word line WL1 connected to the first sub-plane SPL1 may not be connected to a word line WL1 connected to the second sub-plane SPL2. For example, string selection lines SSLd and SSLu connected to the first sub-plane SPL1 may not be connected to string selection lines SSLd and SSLu connected to the second sub-plane SPL2. For example, ground selection lines GSLd and GSLu connected to the first sub-plane SPL1 may not be connected to ground selection lines GSLd and GSLu connected to the second sub-plane SPL2.

FIG. 6A illustrates a memory device 60 according to one or more embodiments, and FIG. 6B illustrates a read operation timing diagram of the memory device 60 of FIG. 6A.

Referring to FIGS. 6A and 6B, the memory device 60 may correspond to an implementation example of the memory device 50 of FIG. 5A, and the description of FIG. 5A may be applied to the embodiment of FIGS. 6A and 6B. A memory cell region CELL may include a first sub-plane SPL1 and a second sub-plane SPL2. Each of the first and second sub-planes SPL1 and SPL2 may include channel structures CH which extend in a vertical direction Z. The memory cell region CELL may further include word lines WL1 to WLn (where n may be a positive integer), string selection lines SSLd and SSLu, ground selection lines GSLd and GSLu, and GIDL control lines GIDL, which are stacked in the vertical direction Z. The memory cell region CELL of FIG. 6A is illustrated in a form where the memory cell region CELL of FIG. 5A is reversed in the vertical direction Z.

The peripheral circuit region PERI may include first and second transistors TR1 and TR2. For example, the first transistor TR1 may be driven by a first control signal CSL_DRV1_EN and may be included in the first CSL driver 51 of FIG. 5A. For example, the first transistor TR1 may be connected between a first common source plate CSL1 and a ground terminal. For example, the second transistor TR2 may be driven by a second control signal CSL_DRV2_EN and may be included in the second CSL driver 52 of FIG. 5A. For example, the second transistor TR2 may be connected between a second common source plate CSL2 and the ground terminal.

The memory device 60 may transfer a ready/busy output signal RnBx, representing state information about the memory device 60, to a memory controller for example. When the memory device 60 is in a busy state (i.e., when internal operations of the memory device 60 are being performed), the memory device 60 may transfer the ready/busy output signal RnBx, representing the busy state, to the memory controller. When the memory device 60 is in a ready state (i.e., when the internal operations of the memory device 60 are not performed or are completed), the memory device 60 may transfer the ready/busy output signal RnBx, representing the ready state, to the memory controller. For example, while the memory device 60 is reading data DATA from a memory cell array (for example, 11 of FIG. 11) in response to a page read command, an interface circuit of the memory device 60 may transfer the ready/busy output signal RnBx, representing the busy state (for example, a low level), to the memory controller.

Hereinafter, a read operation on the first sub-plane SPL1 will be described. In a read period, a selection voltage (for example, a high level) may be applied to a string selection line SSL and a ground selection line GSL. Also, in the read period, the first control signal CSL_DRV1_EN may have an enable level (for example, a high level), and thus, the first transistor TR1 may be turned on. Therefore, a first common source plate CSL1 connected to the first sub-plane SPL1 may be connected to the ground terminal and may maintain a low level.

According to a first case CASE1, when performing a read operation on the first sub-plane SPL1, the first and second control signals CSL_DRV1_EN and CSL_DRV2_EN may be equally controlled. Accordingly, in the read period, the second control signal CSL_DRV2_EN may also have an enable level (for example, a high level), and thus, the second transistor TR2 may also be turned on. Therefore, a second common source plate CSL2 connected to the second sub-plane SPL2 may be connected to the ground terminal and may maintain a low level. At this time, a capacitance may occur between channel structures CH and word lines WL included in the second sub-plane SPL2, and thus, a word line loading time may increase.

According to a second case CASE2, when performing a read operation on the first sub-plane SPL1, the first and second control signals CSL_DRV1_EN and CSL_DRV2_EN may be differently controlled. Accordingly, in the read period, the second control signal CSL_DRV2_EN may also have a disable level (for example, a low level), and thus, the second transistor TR2 may also be turned off. Therefore, the second common source plate CSL2 connected to the second sub-plane SPL2 may be floated. At this time, a capacitance may not occur between channel structures CH and word lines WL included in the second sub-plane SPL2, and thus, a word line loading time may decrease.

In a read operation, a row decoder (for example, 14 of FIG. 1) may apply a certain voltage to a selected word line WL_SEL and an unselected word line WL_UN. At this time, as described above, according to the first case CASE1 and the second case CASE2, a word line loading time may vary, and thus, the voltage waveform shape of each of the selected word line WL_SEL and the unselected word line WL_UN may be changed. For example, in the first case CASE1, a word line loading time may be relatively long, and thus, a voltage slope of each of the selected word line WL_SEL and the unselected word line WL_UN may be relatively gentle. For example, in the second case CASE2, a word line loading time may be relatively short, and thus, the voltage slope of each of the selected word line WL_SEL and the unselected word line WL_UN may be relatively steep.

For example, a period of a t0 time to a t1 time may correspond to a word line setup period. At the t0 time, an operation voltage may start to be applied to the selected word line WL_SEL and unselected word lines WL_UN. In the first case CASE1, a voltage slope may be relatively gentle, and at the t1 time, voltages of the selected word line WL_SEL and the unselected word lines WL_UN may reach the operation voltage. Furthermore, in the second case CASE2, a capacitance may occur between only word lines WL and channel structures CH included in the first sub-plane SPL1, and a capacitance may not occur between word lines WL and channel structures CH included in the second sub-plane SPL2, and thus, a word line loading time may be short, whereby the voltages of the selected word line WL_SEL and the unselected word lines WL_UN may reach the operation voltage at a t1′ time. Accordingly, in the second case CASE2, the word line setup period may decrease by a first time T1 compared to the first case CASE1.

For example, a period of the t1 time to a t2 time may correspond to a precharge period, and a period of the t2 time to a t4 time may correspond to a sensing period. At the t2 time, a read voltage may start to be applied to the selected word line WL_SEL. In the first case CASE1, the voltage of the selected word line WL_SEL may reach the read voltage at a t3 time. Furthermore, in the second case CASE2, a capacitance may occur between only word lines WL and channel structures CH included in the first sub-plane SPL1, and a capacitance may not occur between word lines WL and channel structures CH included in the second sub-plane SPL2, and thus, a word line loading time may be short, whereby the voltage of the selected word line WL_SEL may reach the operation voltage at a t3′ time. Accordingly, in the second case CASE2, the sensing period may increase by a second time T2 compared to the first case CASE1.

For example, a time after a fifth time t4 may correspond to a discharge period. In the first case CASE1, at a t5 time, the voltages of the selected word line WL_SEL and the unselected word lines WL_UN may reach a ground voltage. Furthermore, in the second case CASE2, a capacitance may occur between only word lines WL and channel structures CH included in the first sub-plane SPL1, and a capacitance may not occur between word lines WL and channel structures CH included in the second sub-plane SPL2, and thus, a word line loading time may be short, whereby the voltages of the selected word line WL_SEL and the unselected word lines WL_UN may reach the ground voltage at a t5′ time. Accordingly, in the second case CASE2, the discharge period may decrease by a third time T3 compared to the first case CASE1.

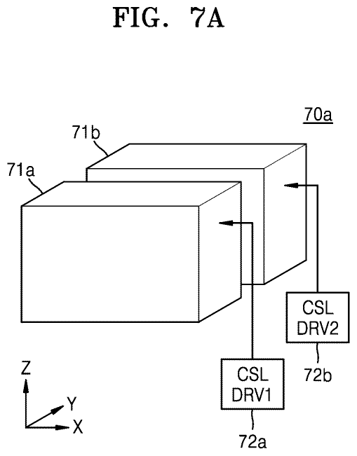

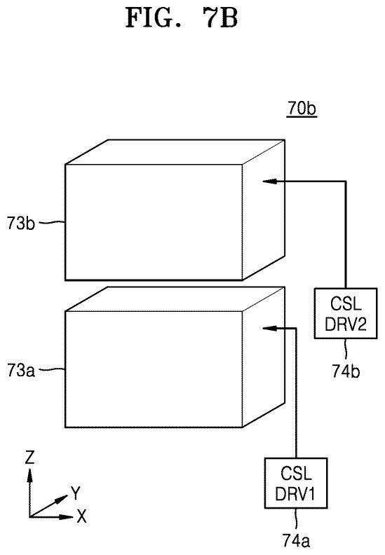

FIG. 7A illustrates connections between first and second sub-planes 71a and 71b and first and second CSL drivers 72a and 72b according to one or more embodiments.

Referring to FIG. 7A, a memory device 70a may include the first and second sub-planes 71a and 71b and the first and second CSL drivers 72a and 72b. In this case, the first sub-plane 71a may be connected to a first common source plate CSL1, and the second sub-plane 71b may be connected to a second common source plate CSL2. The first common source plate CSL1 may be connected to the first CSL driver 72a, and the second common source plate CSL2 may be connected to the second CSL driver 72b.

The first and second sub-planes 71a and 71b may be apart from each other in a first direction Y and may respectively extend in a second direction X and a vertical direction Z. However, the disclosure is not limited thereto, and in one or more embodiments, the first and second sub-planes 71a and 71b may be apart from each other in the second direction X and may respectively extend in the first direction Y and the vertical direction Z. For example, the first and second sub-planes 71a and 71b may be disposed in the same wafer.

FIG. 7B illustrates connections between first and second sub-planes 73a and 73b and first and second CSL drivers 74a and 74b according to one or more embodiments.

Referring to FIG. 7B, a memory device 70b may include the first and second sub-planes 73a and 73b and the first and second CSL drivers 74a and 74b. In this case, the first sub-plane 73a may be connected to a first common source plate CSL1, and the second sub-plane 73b may be connected to a second common source plate CSL2. The first common source plate CSL1 may be connected to the first CSL driver 74a, and the second common source plate CSL2 may be connected to the second CSL driver 74b.

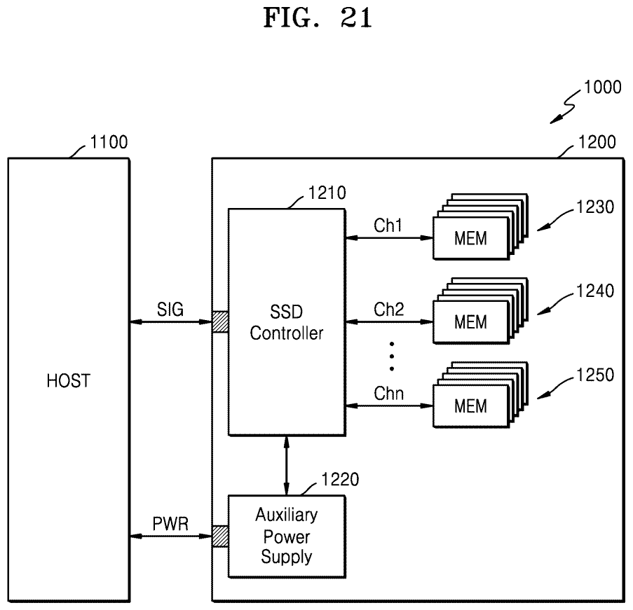

The first and second sub-planes 73a and 73b may be apart from each other in a vertical direction Z and may respectively extend in a second direction X or a first direction Y. For example, the first and second sub-planes 73a and 73b may be disposed in different wafers, the first sub-plane 73a may be disposed in a first memory cell region (for example, CELL1 of FIG. 21), and the second sub-plane 73b may be disposed in a second memory cell region (for example, CELL2 of FIG. 21). However, the disclosure is not limited thereto, and first and second sub-planes 73a and 73b may be disposed in the same wafer.

FIG. 8 is a plan view illustrating a memory device 80 according to one or more embodiments.

Referring to FIG. 8, the memory device 80 may include an MAT, and the MAT may include first and second sub-planes 81a and 81b arranged in a first direction Y. Each of the first and second sub-planes 81a and 81b may extend in a second direction X. For example, the MAT may correspond to the memory cell array 11 of FIG. 1, and thus, the descriptions of FIGS. 1 to 4 may be applied to the embodiment of FIG. 8. For example, the first and second sub-planes 81a and 81b may correspond to the first and second sub-planes 11a and 11b of FIG. 1, and the first and second sub-planes 81a and 81b may be arranged in the first direction Y, and thus, an aspect ratio of a region where the MAT is formed may be improved. Accordingly, the size of the MAT may decrease, and the number of memory dies (i.e., a gross die (GD) value) formed per wafer may increase.

The memory device 80 may further include first to fourth common source plates 82a to 82d. For example, the first and second common source plates 82a and 82b may be apart from each other in the first direction Y, and the third and fourth common source plates 82c and 82d may be apart from each other in the first direction Y. The memory device 80 may further include a row decoder XDEC. For example, the row decoder XDEC may be disposed under a region between the first and second common source plates 82a and 82b and the third and fourth common source plates 82c and 82d. For example, the first and second sub-planes 81a and 81b and the first to fourth common source plates 82a to 82d may be disposed in the memory cell region 41 of FIG. 4, and the row decoder XDEC may be disposed in the peripheral circuit region 42 of FIG. 4.

In one or more embodiments, the row decoder XDEC may include a first row decoder connected to the first sub-plane 81a and a second row decoder connected to the second sub-plane 81b. As described above, the first and second sub-planes 81a and 81b may be respectively connected to different row decoders. Accordingly, word lines connected to the first and second sub-planes 81a and 81b may be independently controlled. In one or more embodiments, a first pass transistor circuit may be connected between the row decoder XDEC and the first sub-plane 81a, and a second pass transistor circuit may be connected between the row decoder XDEC and the second sub-plane 81b. As described above, the first and second sub-planes 81a and 81b may be respectively connected to different pass transistor circuits. Accordingly, word lines connected to the first and second sub-planes 81a and 81b may be independently controlled.

The first sub-plane 81a may include first memory blocks connected to the first common source plate 82a and second memory blocks connected to the third common source plate 82c. The second sub-plane 81b may include third memory blocks connected to the second common source plate 82b and fourth memory blocks connected to the fourth common source plate 82d. In one or more embodiments, the row decoder XDEC may include a first row decoder disposed under a region between the first memory blocks and the second memory blocks and a second row decoder disposed under a region between the third memory blocks and the fourth memory blocks. In one or more embodiments, a first pass transistor circuit may be disposed between the first memory blocks and the row decoder XDEC, and a second pass transistor circuit may be disposed between the second memory blocks and the row decoder XDEC.

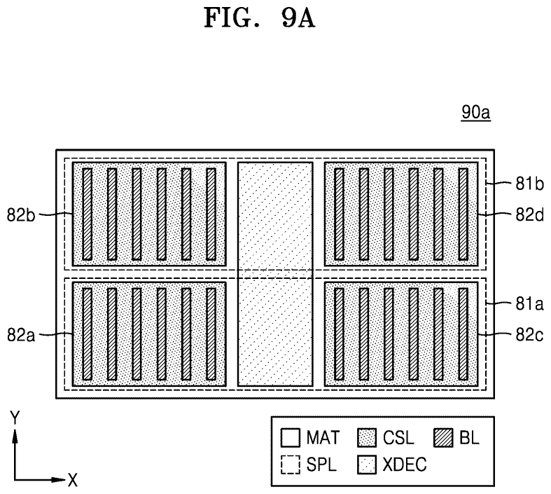

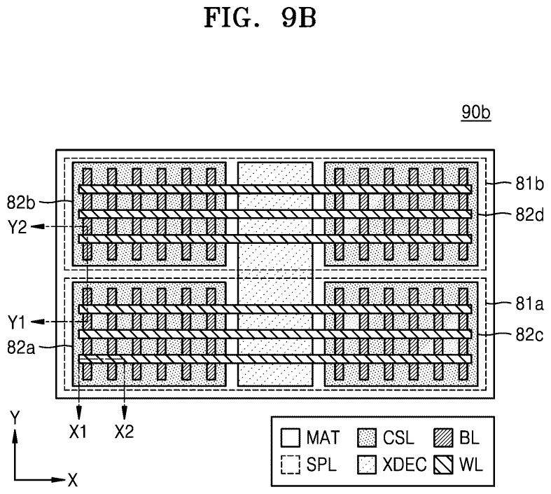

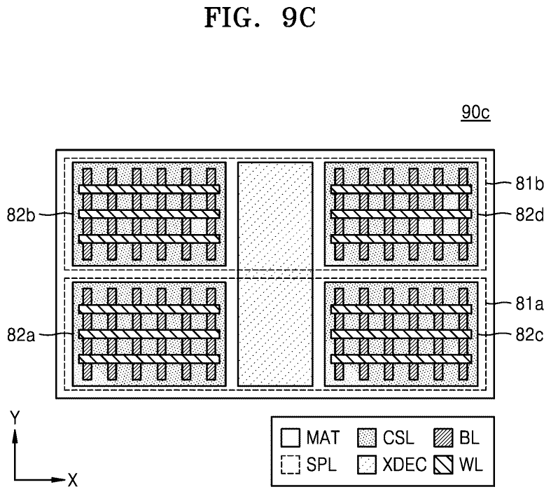

FIG. 9A is a plan view illustrating a memory device 90a according to one or more embodiments. Referring to FIG. 9A, the memory device 90a may correspond to a modification example of the memory device 80 of FIG. 8 and may further include bit lines BL compared to the memory device 80 of FIG. 8. The bit lines BL may extend in a first direction Y and may be apart from one another in a second direction X. For example, bit lines BL connected to a first sub-planes 81a may correspond to the first bit line group BLG1 of FIG. 1, and bit lines BL connected to a second sub-planes 81b may correspond to the second bit line group BLG2 of FIG. 1. As described above, the first and second sub-planes 81a and 81b may be respectively connected to first and second bit line groups BLG1 and BLG2, and page buffers may be disposed under the first and second sub-planes 81a and 81b, and thus, a read time of the memory device 90a may decrease, thereby enhancing the performance of the memory device 90a.

FIG. 9B is a plan view illustrating a memory device 90b according to one or more embodiments.

Referring to FIG. 9B, the memory device 90b may correspond to a modification example of the memory device 90a of FIG. 9A and may further include word lines WL compared to the memory device 90a of FIG. 9A. The word lines WL may extend in a second direction X and may be apart from one another in a first direction Y. For example, each of the word lines WL may extend in the second direction X above a row decoder XDEC.

Memory blocks included in a first sub-plane 81a may be connected to the same word lines WL, and memory blocks included in a second sub-plane 81b may be connected to the same word lines WL. In this case, memory blocks included in first and third common source plates 82a and 82c may be connected to the same word lines WL, and memory blocks included in second and fourth common source plates 82b and 82d may be connected to the same word lines WL.

FIG. 9C is a plan view illustrating a memory device 90c according to one or more embodiments.

Referring to FIG. 9C, the memory device 90c may correspond to a modification example of the memory device 90a of FIG. 9A and may further include word lines WL compared to the memory device 90a of FIG. 9A. The word lines WL may extend in a second direction X and may be apart from one another in a first direction Y. For example, the word lines WL may overlap regions where first to fourth common source plates 82a to 82d are disposed.

First memory blocks connected to the first common source plate 82a among memory blocks included in a first sub-plane 81a may be connected to the same word lines WL, and second memory blocks connected to the third common source plate 82c among memory blocks included in the first sub-plane 81a may be connected to the same word lines WL. Also, third memory blocks connected to the second common source plate 82b among memory blocks included in a second sub-plane 81b may be connected to the same word lines WL, and fourth memory blocks connected to the fourth common source plate 82d among memory blocks included in the second sub-plane 81b may be connected to the same word lines WL.

FIG. 10 illustrates a cross-sectional view taken along line Y1-Y2 of FIG. 9B, according to one or more embodiments, and FIG. 11 illustrates a cross-sectional view taken along line X1-X2 of FIG. 9B, according to one or more embodiments.

Referring to FIGS. 10 and 11, a memory cell region CELL may include a first sub-plane 81a and a second sub-plane 81b, and a dummy block D_BLK may be disposed between the first sub-plane 81a and the second sub-plane 81b. For example, the dummy block D_BLK may not be connected to a bit line or a common source line. For example, the dummy block D_BLK may be floated, but the disclosure is not limited thereto. As described above, according to one or more embodiments, a cut region (for example, a tile cut region) may not be disposed between the first sub-plane 81a and the second sub-plane 81b. For example, input output contact plugs may not be disposed between the first sub-plane 81a and the second sub-plane 81b, and thus, the size of the memory cell region CELL may decrease.

For example, the first and second sub-planes 81a and 81b may be respectively connected to the first and second common source plates 82a and 82b. For example, the first and second sub-planes 81a and 81b may be respectively connected to different bit lines BL1 and BL2. For example, the first and second sub-planes 81a and 81b and the dummy block D_BLK may be respectively connected to different gate electrodes GE. However, the disclosure is not limited thereto, and in one or more embodiments, the first and second sub-planes 81a and 81b and the dummy block D_BLK may be connected to the same gate electrodes GE.

The memory cell region CELL may include an upper substrate U_SUB, first and second common source plates 82a and 82b, a gate structure GS, channel structures CH, a first metal layer M1, first metal contacts MC1, upper bonding vias UBV, and upper bonding pads UBP. The number of metal layers included in the memory cell region CELL may be variously changed according to embodiments. The upper substrate U_SUB may be implemented with polysilicon. For example, the first and second common source plates 82a and 82b may be formed in a plate shape by doping the upper substrate U_SUB with impurities. According to one or more embodiments, the upper substrate U_SUB may be defined as including a plate-shape common source line or a common source plate. The gate structure GS may include a plurality of gate electrodes GE which are stacked in a vertical direction Z, and an insulation layer IL may be disposed between adjacent gate electrodes GE. The channel structures CH may extend in the vertical direction Z on the upper substrate U_SUB or the first and second common source plates 82a and 82b.

The first metal layer M1, the upper bonding vias UBV, and the upper bonding pads UBP may include a metal material, and for example, may include one material or a combination of materials selected from among the group consisting of copper (Cu), aluminum (Al), tungsten (W), titanium (Ti), titanium nitride (TiN), tungsten nitride (WN), tantalum (Ta), tantalum nitride (TaN), and titanium-aluminum-nitride (TiAlN). The first metal contact MC1 may include a conductive material, and for example, may include doped polysilicon, Al, W, Cu, or Ti.

According to one or more embodiments, the first metal layer MC1 may include bit lines BL1 and BL2, which each extend in a first direction Y and are apart from each other in a second direction X. In one or more embodiments, the bit lines BL1 and BL2 may be respectively connected to the channel structures CH through a corresponding metal contact MC1 or drain. Also, the bit lines BL1 and BL2 may be respectively connected to the upper bonding pads UBP through corresponding upper bonding vias UBV.

The peripheral circuit region PERI may include a lower substrate L_SUB, lower metal layers LMa and LMb, lower metal contacts LMCa and LMCb, a lower insulation layer L_IL, lower bonding vias LBV, and lower bonding pads LBP. The number of lower metal layers included in the peripheral circuit region PERI may be variously changed according to embodiments. A plurality of circuit elements (for example, a plurality of transistors 101, 102, and 111) may be disposed on the lower substrate L_SUB. For example, the transistors 101 and 111 may be included in the first page buffer 43a of FIG. 4, and the transistor 102 may be included in the second page buffer 43b of FIG. 4.

FIG. 12 schematically illustrates a memory device 120 having a B-VNAND structure, according to one or more embodiments.

Referring to FIG. 12, the memory device 120 may include a memory cell region CELL and a peripheral circuit region PERI. The peripheral circuit region PERI may be implemented to be substantially similar to the peripheral circuit region PERI of FIGS. 10 and 11, and the descriptions of FIGS. 10 and 11 may be applied to the embodiment of FIG. 12. The peripheral circuit region PERI may include transistors 121 to 123. For example, the transistor 121 may be connected to a bit line, and thus, may be included in a page buffer. For example, the transistor 122 may be connected to a first common source plate CSL1, and thus, may be included in a first CSL driver (for example, 15a of FIG. 1). For example, the transistor 123 may be connected to a second common source plate CSL2, and thus, may be included in a second CSL driver (for example, 15b of FIG. 1).

The memory cell region CELL may include a plurality of channel structures and a plurality of gate electrodes GE. Each of the channel structures may include first and second memory stacks CH_L and CH_U which are stacked. A plurality of channel structures included in a first sub-plane (for example, 11a of FIG. 1) may be connected to the first common source plate CSL1, and a plurality of channel structures included in a second sub-plane (for example, 11b of FIG. 1) may be connected to the second common source plate CSL2.

A plurality of vias V1 may be disposed on the first and second common source plates CSL1 and CSL2, and an upper metal layer BAM may be disposed on the plurality of vias V1. For example, the upper metal layer BAM may correspond to a backside aluminum metal, which is disposed on a backside surface of an upper substrate. The memory cell region CELL may further include input output contacts IOMC. The upper bonding pad UBP may be connected to the first or second common source plate CSL1 or CSL2 through an upper bonding via UBV, a first metal layer M1, an input output contact IOMC, a plurality of vias V1, and an upper metal layer BAM.

FIG. 13 schematically illustrates a memory device 130 having a B-VNAND structure, according to one or more embodiments.

Referring to FIG. 13, the memory device 130 may correspond to a modification example of the memory device 120 of FIG. 12 and may include a memory cell region CELL and a peripheral circuit region PERI. Hereinafter, the difference between the memory device 130 according to one or more embodiments and the memory device 120 of FIG. 12 will be mainly described. The memory cell region CELL may include a plurality of channel structures and a plurality of gate electrodes GE. Each of the channel structures may include first to fourth memory stacks CH_L1, CH_L2, CH_U1, and CH_U2 which are stacked. A plurality of channel structures included in a first sub-plane (for example, 11a of FIG. 1) may be connected to a first common source plate CSL1, and a plurality of channel structures included in a second sub-plane (for example, 11b of FIG. 1) may be connected to a second common source plate CSL2.

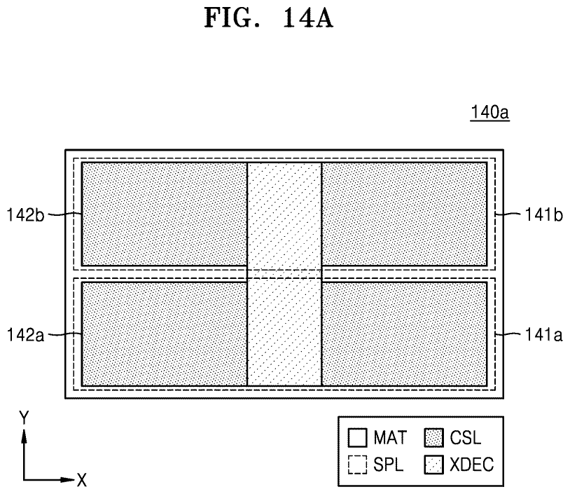

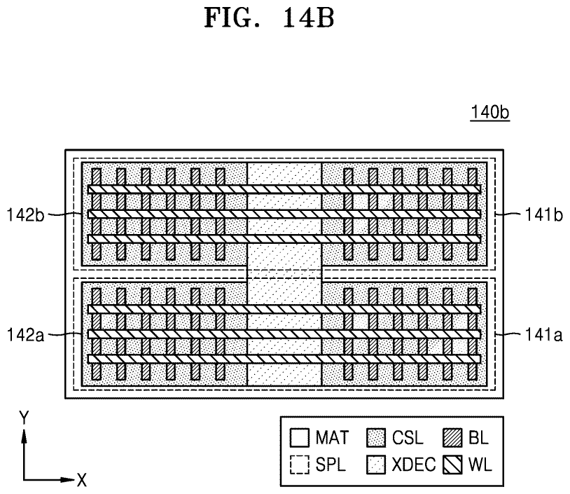

FIG. 14A is a plan view illustrating a memory device 140a according to one or more embodiments.

Referring to FIG. 14A, the memory device 140a may include an MAT, and the MAT may include first and second sub-planes 141a and 141b arranged in a first direction Y. Each of the first and second sub-planes 141a and 141b may extend in a second direction X. The memory device 140a may correspond to a modification example of the memory device 80 of FIG. 8, and the description of FIG. 8 may be applied to the embodiment of FIG. 14A.

The memory device 140a may include first and second common source plates 142a and 142b and a row decoder XDEC. For example, the first and second common source plates 142a and 142b may be apart from each other in the first direction Y and may each extend in the second direction X. For example, the first and second common source plates 142a and 142b may each extend in the second direction X across an upper portion of a row decoder XDEC.

The first sub-plane 141a may include a plurality of memory blocks which are connected to the first common source plate 142a. The second sub-plane 141b may include a plurality of memory blocks which are connected to the second common source plate 142b. For example, the first and second sub-planes 141a and 141b and the first and second common source plates 142a and 142b may be disposed in the memory cell region 41 of FIG. 4, and the row decoder XDEC may be disposed in the peripheral circuit region 42 of FIG. 4.

FIG. 14B is a plan view illustrating a memory device 140b according to one or more embodiments.

Referring to FIG. 14B, the memory device 140b may correspond to a modification example of the memory device 140a of FIG. 14A and may further include bit lines BL compared to the memory device 140a of FIG. 14A. The bit lines BL may extend in a first direction Y and may be apart from one another in a second direction X. For example, bit lines BL connected to a first sub-planes 141a may correspond to the first bit line group BLG1 of FIG. 1, and bit lines BL connected to a second sub-planes 141b may correspond to the second bit line group BLG2 of FIG. 1. As described above, the first and second sub-planes 141a and 141b may be connected to different bit lines BL.

Also, the memory device 140b may further include word lines WL compared to the memory device 140a of FIG. 14A. The word lines WL may extend in a second direction X and may be apart from one another in a first direction Y. For example, each of the word lines WL may extend in the second direction X across an upper portion of a row decoder XDEC. Memory blocks included in the first sub-plane 141a may be connected to the same word lines WL, and memory blocks included in the second sub-plane 141b may be connected to the same word lines WL. In this case, memory blocks connected to a first common source plate 142a may be connected to the same word lines WL, and memory blocks connected to a second common source plate 142b may be connected to the same word lines WL. However, the disclosure is not limited thereto, and as illustrated in FIG. 9C, memory blocks disposed on the left and the right of the row decoder XDEC may be connected to different word lines, in the same sub-plane.

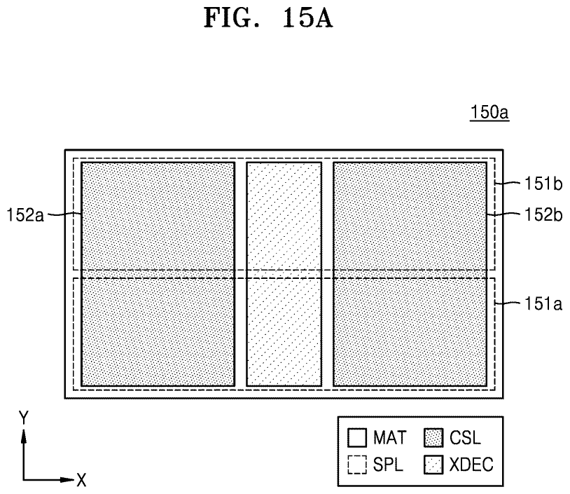

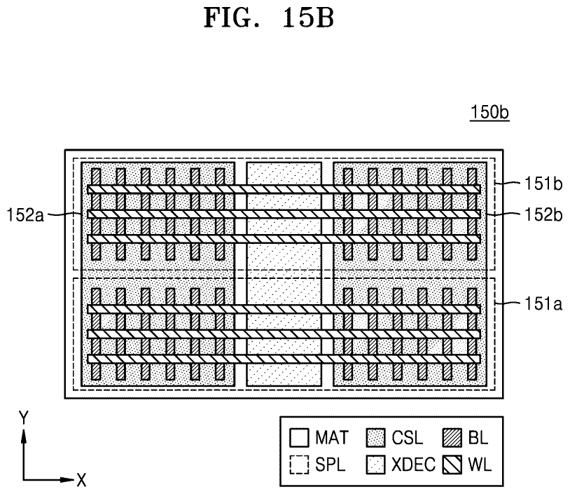

FIG. 15A is a plan view illustrating a memory device 150a according to one or more embodiments.

Referring to FIG. 15A, the memory device 150a may include an MAT, and the MAT may include first and second sub-planes 151a and 151b arranged in a first direction Y. Each of the first and second sub-planes 151a and 151b may extend in a second direction X. The memory device 150a may correspond to a modification example of the memory device 80 of FIG. 8, and the description of FIG. 8 may be applied to the embodiment of FIG. 15A.

The memory device 150a may include first and second common source plates 152a and 152b and a row decoder XDEC. For example, the first and second common source plates 152a and 152b may each extend in the second direction X and may be apart from each other in the first direction Y. The first sub-plane 151a may include first memory blocks connected to the first common source plate 152a and second memory blocks connected to the third common source plate 152c. The first sub-plane 151b may include third memory blocks connected to the first common source plate 152a and fourth memory blocks connected to the second common source plate 152b. For example, the first and second sub-planes 151a and 151b and the first and second common source plates 152a and 152b may be disposed in the memory cell region 41 of FIG. 4, and the row decoder XDEC may be disposed in the peripheral circuit region 42 of FIG. 4.

FIG. 15B is a plan view illustrating a memory device 150b according to one or more embodiments.

Referring to FIG. 15B, the memory device 150b may correspond to a modification example of the memory device 150a of FIG. 15A and may further include bit lines BL compared to the memory device 150a of FIG. 15A. The bit lines BL may extend in a first direction Y and may be apart from one another in a second direction X. For example, bit lines BL connected to a first sub-planes 151a may correspond to the first bit line group BLG1 of FIG. 1, and bit lines BL connected to a second sub-planes 151b may correspond to the second bit line group BLG2 of FIG. 1. As described above, the first and second sub-planes 151a and 151b may be connected to different bit lines BL.

Also, the memory device 150b may further include word lines WL compared to the memory device 150a of FIG. 15A. The word lines WL may extend in a second direction X and may be apart from one another in a first direction Y. For example, each of the word lines WL may extend in the second direction X across an upper portion of a row decoder XDEC. Memory blocks included in the first sub-plane 151a may be connected to the same word lines WL, and memory blocks included in the second sub-plane 151b may be connected to the same word lines WL. However, the disclosure is not limited thereto, and as illustrated in FIG. 9C, memory blocks disposed on the left and the right of the row decoder XDEC may be connected to different word lines, in the same sub-plane.

FIG. 16A is a plan view illustrating a memory device 160a according to one or more embodiments.

Referring to FIG. 16A, the memory device 160a may include an MAT, and the MAT may include first to fourth sub-planes 161a to 161d. For example, the first and second sub-planes 161a and 161b may be arranged in a first direction Y, and the third and fourth sub-planes 161c and 161d may be arranged in the first direction Y. As described above, the first to fourth sub-planes 161a to 161d may be arranged in an array form. The memory device 160a may correspond to a modification example of the memory device 80 of FIG. 8, and the description of FIG. 8 may be applied to the embodiment of FIG. 16A.

The memory device 160a may further include first to fourth common source plates 162a to 162d. For example, the first and second common source plates 162a and 162b may be apart from each other in the first direction Y, and the third and fourth common source plates 162c and 162d may be apart from each other in the first direction Y. The memory device 160a may further include a row decoder XDEC. For example, the row decoder XDEC may be disposed under a region between the first and second common source plates 162a and 162b and the third and fourth common source plates 162c and 162d. For example, the first to fourth sub-planes 161a to 161d and the first to fourth common source plates 162a to 162d may be disposed in the memory cell region 41 of FIG. 4, and the row decoder XDEC may be disposed in the peripheral circuit region 42 of FIG. 4.

In one or more embodiments, the row decoder XDEC may include a first row decoder connected to the first sub-plane 161a, a second row decoder connected to the second sub-plane 161b, a third row decoder connected to the third sub-plane 161c, and a fourth row decoder connected to the fourth sub-plane 161d. As described above, the first to fourth sub-planes 161a to 161d may be respectively connected to different row decoders. Accordingly, word lines connected to the first to fourth sub-planes 161a to 161d may be independently controlled.

In one or more embodiments, a first pass transistor circuit may be connected between the row decoder XDEC and the first sub-plane 161a, a second pass transistor circuit may be connected between the row decoder XDEC and the second sub-plane 161b, a third pass transistor circuit may be connected between the row decoder XDEC and the third sub-plane 161c, and a fourth pass transistor circuit may be connected between the row decoder XDEC and the fourth sub-plane 161d. As described above, the first to fourth sub-planes 161a to 161d may be respectively connected to different pass transistor circuits. Accordingly, word lines connected to the first to fourth sub-planes 161a to 161d may be independently controlled.

FIG. 16B is a plan view illustrating a memory device 160b according to one or more embodiments.

Referring to FIG. 16B, the memory device 160b may correspond to a modification example of the memory device 160a of FIG. 16A. The memory device 160b may include first to fourth sub-planes 161a to 161d, first and second common source plates 163a and 163b, and a row decoder XDEC. For example, the first and second common source plates 163a and 163b may be apart from each other in a first direction Y and may each extend in a second direction X. For example, the first and second common source plates 163a and 163b may each extend in the second direction X across an upper portion of the row decoder XDEC. The first sub-plane 161a may include memory blocks which are connected to the first common source plate 163a. The second sub-plane 161b may include memory blocks which are connected to the second common source plate 163b.

FIG. 16C is a plan view illustrating a memory device 160c according to one or more embodiments.

Referring to FIG. 16C, the memory device 160c may correspond to a modification example of the memory device 160a of FIG. 16A. The memory device 160c may include first to fourth sub-planes 161a to 161d, first and second common source plates 164a and 164b, and a row decoder XDEC. For example, the first and second common source plates 164a and 164b may each extend in a first direction Y and may be apart from each other in a second direction X. The first sub-plane 161a may include first memory blocks connected to the first common source plate 164a and second memory blocks connected to the third common source plate 164b. The second sub-plane 161b may include third memory blocks connected to the first common source plate 164a and fourth memory blocks connected to the second common source plate 164b.

FIG. 17A is a plan view illustrating a memory device 170a according to one or more embodiments.

Referring to FIG. 17A, the memory device 170a may correspond to a modification example of the memory device 160a of FIG. 16A and may further include bit lines BL compared to the memory device 160a of FIG. 16A. The bit lines BL may each extend in a first direction Y and may be apart from one another in a second direction X. As described above, the first to fourth sub-planes 161a to 161d may be connected to different bit lines BL.

FIG. 17B is a plan view illustrating a memory device 170b according to one or more embodiments.

Referring to FIG. 17B, the memory device 170b may correspond to a modification example of the memory device 170a of FIG. 17A and may further include bit lines BL compared to the memory device 170a of FIG. 17A. The word lines WL may extend in a second direction X and may be apart from one another in a first direction Y. For example, each of the word lines WL may extend in the second direction X across an upper portion of a row decoder XDEC. Memory blocks included in first and third sub-planes 161a and 161c may be connected to the same word lines WL, and memory blocks included in second and fourth sub-planes 161b and 161d may be connected to the same word lines WL.

FIG. 17C is a plan view illustrating a memory device 170c according to one or more embodiments.

Referring to FIG. 17C, the memory device 170c may correspond to a modification example of the memory device 170a of FIG. 17A and may further include word lines WL compared to the memory device 170a of FIG. 17A. The word lines WL may extend in a second direction X and may be apart from one another in a first direction Y. For example, the word lines WL may overlap regions where first to fourth common source plates 162a to 162d are disposed.

Memory blocks included in a first sub-plane 161a may be connected to the same word lines WL, memory blocks included in a second sub-plane 161b may be connected to the same word lines WL, memory blocks included in a third sub-plane 161c may be connected to the same word lines WL, and memory blocks included in a fourth sub-plane 161d may be connected to the same word lines WL. As described above, different sub-planes may be respectively connected to different word lines.

FIG. 18A is a plan view illustrating a memory device 180a according to one or more embodiments.

Referring to FIG. 18A, the memory device 180a may include an MAT, and the MAT may include first and second sub-planes 181a and 181b arranged in a second direction X. Each of the first and second sub-planes 181a and 181b may extend in a first direction Y. For example, the MAT may correspond to the memory cell array 11 of FIG. 1, the first and second sub-planes 181a and 181b may correspond to the first and second sub-planes 11a and 11b of FIG. 1, and thus, the descriptions of FIGS. 1 to 4 may be applied to the embodiment of FIG. 18A. Also, the memory device 180a may correspond to a modification example of the memory device 80 of FIG. 8, and the description of FIG. 8 may be applied to the embodiment of FIG. 18A.

The memory device 180a may further include first to fourth common source plates 182a to 182d. For example, the first and second common source plates 182a and 182b may be apart from each other in the first direction Y, and the third and fourth common source plates 182c and 182d may be apart from each other in the first direction Y. The memory device 180a may further include a row decoder XDEC. For example, the row decoder XDEC may be disposed under a region between the first and second common source plates 182a and 182b and the third and fourth common source plates 182c and 182d.

FIG. 18B is a plan view illustrating a memory device 180b according to one or more embodiments.

Referring to FIG. 18B, the memory device 180b may correspond to a modification example of the memory device 180a of FIG. 18A. The memory device 180b may include first and second sub-planes 181a and 181b and first and second common source plates 183a and 183b. For example, the first and second common source plates 183a and 183b may each extend in a first direction Y and may be apart from each other in a second direction X. The first sub-plane 181a may include memory blocks which are connected to the first common source plate 183a. The second sub-plane 181b may include memory blocks which are connected to the second common source plate 183b.

FIG. 19 is a plan view illustrating a memory device 190 according to one or more embodiments.

Referring to FIG. 19, the memory device 190 may include first and second MATs MAT1 and MAT2 arranged in a first direction Y and third and fourth MATs MAT3 and MAT4 arranged in the first direction Y. In this case, the first and third MATs MAT1 and MAT3 may be adjacent to each other in a second direction X, and the second and fourth MATs MAT2 and MAT4 may be adjacent to each other in the second direction X. As described above, the first to fourth MATs MAT1 to MAT4 may be arranged in a 2×2 array form. For example, each of the first to fourth MATs MAT1 to MAT4 may correspond to the memory cell array 11 of FIG. 1.

At least one of the first to fourth MATs MAT1 to MAT4 may correspond to the MATs illustrated in FIGS. 8 to 18B, and the descriptions of FIGS. 8 to 18B may be applied to the embodiment of FIG. 19. For example, each of the first to fourth MATs MAT1 to MAT4 may include two sub-planes. For example, the first MAT MAT1 may include first and second sub-planes SPL1a and SPL1b, bit lines BL respectively connected to the first and second sub-planes SPL1a and SPL1b, first to fourth common source plates CSL, and a row decoder XDEC1.

In one or more embodiments, each of the first to fourth MATs MAT1 to MAT4 may include three or more sub-planes. In one or more embodiments, the memory device 190 may include two MATs which are arranged in a 2×1 array form. In one or more embodiments, the memory device 190 may include six MATs which are arranged in a 2×3 array form or a 3×2 array form. In one or more embodiments, the memory device 190 may include eight MATs which are arranged in a 2×4 array form. In one or more embodiments, the memory device 190 may include nine MATs which are arranged in a 3×3 array form.

FIG. 20 is a view illustrating a memory device 500 according to one or more embodiments of the disclosure.

Referring to FIG. 20, the memory device 500 may have a C2C structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 500 may include the at least one upper chip including the cell region. For example, as illustrated in FIG. 20, the memory device 500 may include two upper chips. However, the number of the upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 20. However, embodiments of the disclosure are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b and 220c formed on the first substrate 210. An interlayer insulating layer 215 including one or more insulating layers may be provided on the plurality of circuit elements 220a, 220b and 220c, and a plurality of metal lines electrically connected to the plurality of circuit elements 220a, 220b and 220c may be provided in the interlayer insulating layer 215. For example, the plurality of metal lines may include first metal lines 230a, 230b and 230c connected to the plurality of circuit elements 220a, 220b and 220c, and second metal lines 240a, 240b and 240c formed on the first metal lines 230a, 230b and 230c. The plurality of metal lines may be formed of at least one of various conductive materials. For example, the first metal lines 230a, 230b and 230c may be formed of tungsten having a relatively high electrical resistivity, and the second metal lines 240a, 240b and 240c may be formed of copper having a relatively low electrical resistivity.

The first metal lines 230a, 230b and 230c and the second metal lines 240a, 240b and 240c are illustrated and described in the present embodiments. However, embodiments of the disclosure are not limited thereto. In certain embodiments, at least one or more additional metal lines may further be formed on the second metal lines 240a, 240b and 240c. In this case, the second metal lines 240a, 240b and 240c may be formed of aluminum, and at least some of the additional metal lines formed on the second metal lines 240a, 240b and 240c may be formed of copper having an electrical resistivity lower than that of aluminum of the second metal lines 240a, 240b and 240c.

The interlayer insulating layer 215 may be disposed on the first substrate 210 and may include an insulating material such as silicon oxide and/or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (i.e., the Z-axis direction) perpendicular to a top surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked on the third substrate 410 in a direction (i.e., the Z-axis direction) perpendicular to a top surface of the third substrate 410. Each of the second substrate 310 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In one or more embodiments, as illustrated in a region ‘A1’, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a Y-axis direction) parallel to the top surface of the second substrate 310.

In one or more embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. The memory device 500 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 332 and 333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 331 and 332 penetrated by the lower channel LCH is less than the number of the upper word lines 333 to 338 penetrated by the upper channel UCH in the region ‘A2’. However, embodiments of the disclosure are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 20, the first through-electrode THV1 may penetrate the common source line 320 and the plurality of word lines 330. In certain embodiments, the first through-electrode THV1 may further penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In one or more embodiments, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Referring continuously to FIG. 20, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. In one or more embodiments, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405 and 406 may be disposed in the external pad bonding region PA. Referring to FIG. 20, a lower insulating layer 201 may cover a bottom surface of the first substrate 210, and a first input/output pad 205 may be formed on the lower insulating layer 201. The first input/output pad 205 may be connected to at least one of a plurality of the circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 to electrically isolate the first input/output contact plug 203 from the first substrate 210.

An upper insulating layer 401 covering a top surface of the third substrate 410 may be formed on the third substrate 410. A second input/output pad 405 and/or a third input/output pad 406 may be disposed on the upper insulating layer 401. The second input/output pad 405 may be connected to at least one of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

In one or more embodiments, the third substrate 410 may not be disposed in a region in which the input/output contact plug is disposed. For example, as illustrated in a region ‘B’, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

In one or more embodiments, as illustrated in a region ‘B1’, the third input/output contact plug 404 may extend in a third direction (e.g., the Z-axis direction), and a diameter of the third input/output contact plug 404 may become progressively greater toward the upper insulating layer 401. In other words, a diameter of the channel structure CH described in the region ‘A1’ may become progressively less toward the upper insulating layer 401, but the diameter of the third input/output contact plug 404 may become progressively greater toward the upper insulating layer 401. For example, the third input/output contact plug 404 may be formed after the second cell region CELL2 and the first cell region CELL1 are bonded to each other by the bonding method.

In certain embodiments, as illustrated in a region ‘B2’, the third input/output contact plug 404 may extend in the third direction (e.g., the Z-axis direction), and a diameter of the third input/output contact plug 404 may become progressively less toward the upper insulating layer 401. In other words, like the channel structure CH, the diameter of the third input/output contact plug 404 may become progressively less toward the upper insulating layer 401. For example, the third input/output contact plug 404 may be formed together with the cell contact plugs 440 before the second cell region CELL2 and the first cell region CELL1 are bonded to each other.

In certain embodiments, the input/output contact plug may overlap with the third substrate 410. For example, as illustrated in a region ‘C’, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

In one or more embodiments, as illustrated in a region ‘C1’, an opening 408 may be formed to penetrate the third substrate 410, and the second input/output contact plug 403 may be connected directly to the second input/output pad 405 through the opening 408 formed in the third substrate 410. In this case, as illustrated in the region ‘C1’, a diameter of the second input/output contact plug 403 may become progressively greater toward the second input/output pad 405. However, embodiments of the disclosure are not limited thereto, and in certain embodiments, the diameter of the second input/output contact plug 403 may become progressively less toward the second input/output pad 405.

In certain embodiments, as illustrated in a region ‘C2’, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region ‘C2’, a diameter of the contact 407 may become progressively greater toward the second input/output pad 405, and a diameter of the second input/output contact plug 403 may become progressively less toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In certain embodiments illustrated in a region ‘C3’, a stopper 409 may further be formed on a bottom end of the opening 408 of the third substrate 410, as compared with the embodiments of the region ‘C2’. The stopper 409 may be a metal line formed in the same layer as the common source line 420. Alternatively, the stopper 409 may be a metal line formed in the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 303 and 304 of the first cell region CELL1 may become progressively less toward the lower metal pattern 371e or may become progressively greater toward the lower metal pattern 371e.

Meanwhile, in one or more embodiments, a slit 411 may be formed in the third substrate 410. For example, the slit 411 may be formed at a certain position of the external pad bonding region PA. For example, as illustrated in a region ‘D’, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

In one or more embodiments, as illustrated in a region ‘D1’, the slit 411 may be formed to penetrate the third substrate 410. For example, the slit 411 may be used to prevent the third substrate 410 from being finely cracked when the opening 408 is formed. However, embodiments of the disclosure are not limited thereto, and in certain embodiments, the slit 411 may be formed to have a depth ranging from about 60% to about 70% of a thickness of the third substrate 410.

In certain embodiments, as illustrated in a region ‘D2’, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In certain embodiments, as illustrated in a region ‘D3’, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Since the insulating material 413 is formed in the slit 411, it is possible to prevent a voltage provided through the second input/output pad 405 from affecting a metal layer disposed on the third substrate 410 in the word line bonding region WLBA.

Meanwhile, in certain embodiments, the first to third input/output pads 205, 405 and 406 may be selectively formed. For example, the memory device 500 may be realized to include only the first input/output pad 205 disposed on the first substrate 210, to include only the second input/output pad 405 disposed on the third substrate 410, or to include only the third input/output pad 406 disposed on the upper insulating layer 401.

In one or more embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

According to embodiments, a memory cell array included in each of the first and second cell regions CELL1 and CELL2 of the memory device 500 may be divided into a plurality of sub-planes and may respectively connect the plurality of sub-planes to a plurality of common source plates (for example, 320). In this case, the plurality of common source plates may be respectively connected to a plurality of CSL drivers, and the plurality of common source plates may be independently driven by the plurality of CSL drivers. For example, the plurality of CSL drivers may be disposed in the peripheral circuit region PERI. Therefore, a CSL driver connected to an operating sub-plane among the plurality of CSL drivers may be selectively enabled. Accordingly, CSL drivers which are not connected to the operating sub-plane may be disabled, and thus, the power consumption of the memory device 500 may decrease.

FIG. 21 illustrates a solid state drive (SSD) including a memory device according to one or more embodiments.

Referring to FIG. 21, an SSD system 1000 may include a host 1100 and an SSD 1200. The SSD 1200 may transmit or receive a signal to or from the host 1100 through a signal connector and may be supplied with power through a power connector. The SSD 1200 may include an SSD controller 1210, an auxiliary power supply 1220, and memory devices 1230, 1240, and 1250. The memory devices 1230, 1240, and 1250 may each be a vertical stack NAND flash memory device. In this case, the SSD 1200 may be implemented by using the embodiments described above with reference to FIGS. 1 to 20.

According to an aspect of the disclosure, a method of operating a non-volatile memory device including a first sub-plane and a second sub-plane, may include: performing an operation on the first sub-plane and not the second sub-plane by: enabling a first common source line driver electrically connected to the first sub-plane; and disabling a second common source line driver electrically connected to the second sub-plane; and performing the operation on the second sub-plane and not the first sub-plane by: enabling the second common source line driver; and disabling the first common source line driver.

The enabling the first common source line driver may include applying a bias voltage to a first common source plate electrically connected to the first sub-plane, using the first common source line driver. The disabling the second common source line driver may include floating a second common source plate electrically connected to the second sub-plane, using the second common source line driver. The enabling the second common source line driver may include applying the bias voltage to the second common source plate. The disabling the first common source line driver may include floating the first common source plate, using the first common source line driver.

The operation may be a read operation.

One or more embodiments herein may constitute an improvement to computer functionality (i.e. improving the functioning of the computer itself) by providing novel memory devices and operation thereof. This improves computational performance by reducing power consumption and/or increasing memory access speed, solving a problem in the realm of computer networks.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A non-volatile memory device comprising:
a memory cell region comprising at least one memory cell array and upper bonding pads, wherein the at least one memory cell array comprises:
a plurality of sub-planes disposed in a first direction; and
a plurality of common source plates respectively electrically connected to the plurality of sub-planes; and
a peripheral circuit region comprising:
lower bonding pads, the peripheral circuit region being electrically connected to the memory cell region in a vertical direction by the upper bonding pads and the lower bonding pads; and
a plurality of common source line drivers respectively electrically connected to the plurality of common source plates, and configured to independently drive the plurality of common source plates.

2. The non-volatile memory device of claim 1,
wherein the plurality of sub-planes comprises a first sub-plane and a second sub-plane,
wherein the plurality of common source plates comprises a first common source plate electrically connected to the first sub-plane and a second common source plate electrically connected to the second sub-plane,
wherein the plurality of common source line drivers comprises a first common source line driver electrically connected to the first common source plate and a second common source line driver electrically connected to the second common source plate, and
wherein in an operation on the first sub-plane, the first common source line driver is configured to be enabled, and the second common source line driver is configured to be disabled.

3. The non-volatile memory device of claim 2, wherein, in the operation on the first sub-plane:
the first common source line driver is configured to apply a bias voltage to the first common source plate, and
the second common source line driver is configured to be disabled, and the second common source plate is configured to be floated.

4. The non-volatile memory device of claim 1, wherein the at least one memory cell array further comprises a word line electrically connected to the plurality of sub-planes.

5. The non-volatile memory device of claim 1, wherein the at least one memory cell array further comprises a plurality of word lines respectively electrically connected to the plurality of sub-planes.

6. The non-volatile memory device of claim 2,
wherein the memory cell region further comprises:
a first bit line group electrically connected to the first sub-plane; and
a second bit line group electrically connected to the second sub-plane,
wherein the peripheral circuit region further comprises:
a plurality of first page buffers electrically connected to the first sub-plane through the first bit line group; and
a plurality of second page buffers electrically connected to the second sub-plane through the second bit line group.

7. The non-volatile memory device of claim 1,
wherein each of the plurality of sub-planes comprises a plurality of memory blocks, and
wherein each of the plurality of memory blocks comprises:
a channel structure extending in the vertical direction; and
a plurality of word lines electrically connected to the channel structure.

8. The non-volatile memory device of claim 1,
wherein each of the plurality of sub-planes comprises a plurality of memory blocks, and
wherein each of the plurality of memory blocks comprises:
a plurality of memory stacks stacked in the vertical direction and each extending in the vertical direction; and
a plurality of word lines electrically connected to the plurality of memory stacks.

9. A non-volatile memory device comprising:
a memory cell region comprising:
at least one memory cell array comprising:
a first sub-plane;
a second sub-plane adjacent to the first sub-plane in a first direction;
a third sub-plane adjacent to the first sub-plane in a second direction intersecting the first direction;
a fourth sub-plane adjacent to the third sub-plane in the first direction and adjacent to the second sub-plane in the second direction; and
a plurality of common source plates electrically connected to the first sub-plane, the second sub-plane, the third sub-plane, and the fourth sub-plane; and
upper bonding pads; and
a peripheral circuit region comprising:
lower bonding pads, the peripheral circuit region being electrically connected to the memory cell region in a vertical direction by the upper bonding pads and the lower bonding pads; and
a plurality of common source line drivers respectively electrically connected to the plurality of common source plates, wherein the plurality of common source line drivers are configured to independently drive the plurality of common source plates.

10. The non-volatile memory device of claim 9,
wherein the plurality of common source plates comprise:
a first common source plate electrically connected to the first sub-plane and the third sub-plane; and
a second common source plate electrically connected to the second sub-plane and the fourth sub-plane,
wherein the plurality of common source line drivers comprise:
a first common source line driver electrically connected to the first common source plate; and
a second common source line driver electrically connected to the second common source plate, and
wherein in an operation on the first sub-plane or the third sub-plane, the first common source line driver is configured to be enabled, and the second common source line driver is configured to be disabled.

11. The non-volatile memory device of claim 9,
wherein the plurality of common source plates comprises:
a first common source plate electrically connected to the first sub-plane and the second sub-plane; and
a second common source plate electrically connected to the third sub-plane and the fourth sub-plane,
wherein the plurality of common source line drivers comprises:
a first common source line driver electrically connected to the first common source plate; and
a second common source line driver electrically connected to the second common source plate, and
wherein in an operation on the first sub-plane or the second sub-plane, the first common source line driver is configured to be enabled, and the second common source line driver is configured to be disabled.

12. The non-volatile memory device of claim 9,
wherein the plurality of common source plates comprises:
a first common source plate electrically connected to the first sub-plane;
a second common source plate electrically connected to the second sub-plane;
a third common source plate electrically connected to the third sub-plane; and
a fourth common source plate electrically connected to the fourth sub-plane,
wherein the plurality of common source line drivers comprises:
a first common source line driver electrically connected to the first common source plate;
a second common source line driver electrically connected to the second common source plate;
a third common source line driver electrically connected to the third common source plate; and
a fourth common source line driver electrically connected to the fourth common source plate, and
wherein in an operation on the first sub-plane, the first common source line driver is configured to be enabled, and the second common source line driver, the third common source line driver, and the fourth common source line driver are disabled.

13. The non-volatile memory device of claim 9,
wherein the plurality of common source plates comprises:
a first common source plate electrically connected to the first sub-plane;
a second common source plate electrically connected to the second sub-plane;
a third common source plate electrically connected to the third sub-plane; and
a fourth common source plate electrically connected to the fourth sub-plane,
wherein the plurality of common source line drivers comprises:
a first common source line driver electrically connected to the first common source plate and the fourth common source plate; and
a second common source line driver electrically connected to the second common source plate and the third common source plate, and
wherein in an operation on the first sub-plane, the first common source line driver is configured to be enabled, and the second common source line driver is configured to be disabled.

14. The non-volatile memory device of claim 9, wherein the at least one memory cell array further comprises a word line electrically connected to the first sub-plane, the second sub-plane, the third sub-plane, and the fourth sub-plane.

15. The non-volatile memory device of claim 9, wherein the at least one memory cell array further comprises a plurality of word lines respectively electrically connected to the first sub-plane, the second sub-plane, the third sub-plane, and the fourth sub-plane.

16. The non-volatile memory device of claim 9,
wherein the memory cell region further comprises:
a first bit line group electrically connected to the first sub-plane;
a second bit line group electrically connected to the second sub-plane;
a third bit line group electrically connected to the third sub-plane; and
a fourth bit line group electrically connected to the fourth sub-plane, and
wherein the peripheral circuit region further comprises:
a plurality of first page buffers electrically connected to the first sub-plane through the first bit line group;
a plurality of second page buffers electrically connected to the second sub-plane through the second bit line group;
a plurality of third page buffers electrically connected to the third sub-plane through the third bit line group; and
a plurality of fourth page buffers electrically connected to the fourth sub-plane through the fourth bit line group.

17. The non-volatile memory device of claim 9,
wherein each of the first sub-plane, the second sub-plane, the third sub-plane, and the fourth sub-plane comprises a plurality of memory blocks, and
wherein each of the plurality of memory blocks comprises:
a plurality of memory stacks stacked in the vertical direction and each extending in the vertical direction; and
a plurality of word lines electrically connected to the plurality of memory stacks.

18. A non-volatile memory device comprising:
a memory cell region comprising:
at least one memory cell array comprising:
a first sub-plane and a second sub-plane arranged in a second direction;
a first common source plate electrically connected to the first sub-plane; and
a second common source plate electrically connected to the second sub-plane; and
upper bonding pads; and
a peripheral circuit region comprising:
lower bonding pads, the peripheral circuit region being electrically connected to the memory cell region in a vertical direction by the upper bonding pads and the lower bonding pads;
a first common source line driver electrically connected to the first common source plate; and
a second common source line driver electrically connected to the second common source plate,
wherein the first common source line driver and the second common source line driver are configured to independently drive the first common source plate and the second common source plate.

19. The non-volatile memory device of claim 18, wherein, in an operation on the first sub-plane,
the first common source line driver is configured to be enabled and apply a bias voltage to the first common source plate, and
the second common source line driver is configured to be disabled, and the second common source plate is configured to be floated.

20. The non-volatile memory device of claim 18, wherein the at least one memory cell array further comprises a word line electrically connected to the first sub-plane and the second sub-plane.
